(19) United States
(12) Patent Application Publication
(10) Pub. No.: US 2019/0198442 A1
(43) Pub. Date: Jun. 27, 2019

(54) Feol/Beol Heterogeneous Integration

(71) Applicant: Sarda Technologies, Inc., Durham, NC (US)

(72) Inventor: William E. Batchelor, Raleigh, NC (US)

(21) Appl. No.: 16/228,345

(22) Filed: Dec. 20, 2018

Related U.S. Application Data
(60) Provisional application No. 62/609,278, filed on Dec. 21, 2017.
(60) Provisional application No. 62/782,625, filed on Dec. 20, 2018.

(51) Int. Cl. H01L 23/528; H01L 29/20; H01L 29/417; H01L 29/423; H01L 23/31; H01L 23/535; H01L 23/522; H01L 29/40; H01L 21/56; H01L 21/768

(52) U.S. Cl. CPC H01L 23/528; H01L 29/20; H01L 29/41725; H01L 29/42372; H01L 23/3171; H01L 21/76895; H01L 23/3192; H01L 23/5226; H01L 29/401; H01L 21/56; H01L 23/535

(57) ABSTRACT

Devices and methods are described for fabricating field effect transistors (FET) using compound semiconductor front end of line (FEOL) integrated with back end of line (BEOL) technologies for applications including power management and communications. Wafer-level FEOL processing with a minimum number of thin interconnects may be used to produce multiple chiplets, which are small, high current density functional building blocks. Chiplets may have tight source/drain finger pitch, high gate width per area, and minimum lateral current flow, to reduce resistance, FEOL process complexity, and cost. Panel-level BEOL processing may serve as an inexpensive extension of FEOL processes. BEOL may form multiple interconnect layers and via bars with progressively increasing thickness and cross section area. These BEOL interconnects and via bars connect together the parallel chiplets, handle lateral flow of high current and reduce electrical and thermal resistance the FETs to increase current carrying capacity of the FETs.

### CROSS REFERENCE TO RELATED APPLICATIONS

This application claims the priority benefit of, pending U.S. provisional patent application No. 62/609,278, filed Dec. 21, 2017, and titled, “FRONT END OF LINE AND INTEGRATED BACK END OF LINE GaAs DEVICE,” and pending U.S. provisional patent application No. 62/782,625, filed concurrently with this application on Dec. 20, 2018, and titled, “FEOL/BEOL HETEROGENEOUS INTEGRATION,” which are all incorporated by reference in their entirety.

### FIELD OF THE TECHNOLOGY

The present invention relates to semiconductors devices, and more particularly to field effect transistor (FET) devices for use in power management, communications and applications including semiconductor die, fabricated using wafer-level, front end of line (FEOL), compound semiconductor, including gallium arsenide (GaAs), gallium oxide (Ga2O3), gallium nitride (GaN) process technologies, embedded in a substrate with interconnect layers fabricated using back end of line (BEOL) process technologies.

### SUMMARY

A device and method are described for a front end of line (FEOL) and integrated back end of line (BEOL) field effect transistor (FET) device. The FET includes one or more semiconductor die, fabricated using FEOL process technologies, embedded in a substrate with multiple metal layers fabricated using BEOL process technologies.

The semiconductor die may be fabricated using wafer-level FEOL gallium arsenide (GaAs), gallium oxide (Ga₂O₃) or gallium nitride (GaN) process technologies, and may include many chiplets. Each chiplet may be a functional building block including many source, drain and gate fingers in an active area, and source, drain and gate conductors in a non-active area. A gate width per unit area (Wg/A) and, hence, current density of each chiplet may be increased through use of a novel layout, which reduces a source/drain finger pitch in the active FET area, increases the gate width of each finger without materially increasing the non-active area. Thin FEOL metal layers may serve to reduce the size of the source/drain fingers. Lateral current flow in the thin FEOL metal interconnect layers may be a very low current flow in each of many parallel source/drain fingers in each chiplet. In the non-active area, a thin but large cross section area of source, drain and gate conductors interconnect the source, drain and gate fingers, respectively, within each chiplet and provide vertical connections to substantially thicker, hence substantially lower resistance, metal layers fabricated using low cost BEOL process technologies. At completion of FEOL processing, the semiconductor die may not be a fully functional FET because the chiplets may not be fully connected to each other. The FEOL metal layers used for the source, drain and gate conductors are generally relatively thin (typically a few microns), which is sufficient for high current vertical flow to the substantially thicker BEOL metal layers, but may be too thin to interconnect the chiplets on the semiconductor die. The semiconductor die may include one or more metal interconnect layers and a final passivation layer with passivation openings to the source, drain and gate conductors.

One or more of the incomplete semiconductor die may be embedded in a substrate. Low cost BEOL process technologies may be used to form multiple metal layers, each with a progressively increasing thickness and cross section area, and via bars that provide horizontal, in addition to vertical, interconnection of various features in adjacent metal layers. Lateral flow of high current across the large area FET device may traverse these ultra low resistance metal layers and via bars, whose total thickness may exceed 100 microns, which may be more than ten times the total thickness of the FEOL metal layers.

The BEOL metal layers and via bars may employ a larger area than the area of the semiconductor die, which further lowers the electrical and thermal resistance and increases the amount of heat spreading material and, hence, thermal mass/time constant.

### BRIEF DESCRIPTION OF THE DRAWINGS

Certain embodiments of the present technology are illustrated by the accompanying figures. It will be understood that the figures are not necessarily to scale and that details not necessary for an understanding of the technology or that render other details difficult to perceive may be omitted. It will be understood that the technology is not necessarily limited to the particular embodiments illustrated herein.

FIG. 1A is a top plan view illustrating a heterogeneously integrated power stage with a FEOL and integrated BEOL FET device, in accordance with aspects of the technology.

FIG. 1B is a bottom view of the heterogeneously integrated power stage of FIG. 1A.

FIG. 1C is a cross section view of the heterogeneously integrated power stage of FIG. 1A along line g-g.

FIG. 1D is an enlargement of a semiconductor die fabricated using FEOL process technologies of FIGS. 1A-1C.

FIG. 2A illustrates general features of the die segment of the die of FIG. 1D.

FIG. 2B illustrates general features of a section of a die segment of a die of FIG. 1D that will be referenced for providing detailed illustration and descriptions of components of the die.

FIG. 3 illustrates various separate layers of the section of FIG. 2B.

FIG. 4A illustrates ohmic metal details of the die segment of the die of FIG. 1D.

FIG. 4B is a section of a die segment for illustrating details of the ohmic layer of FIG. 3.

FIG. 5A illustrates gate metal details of the die segment 110 of the die of FIG. 1D.

FIG. 5B is a section of the die segment for illustrating details of gate metal layer of FIG. 3.

FIG. 6A illustrates gate metal of FIG. 5A overlaid on ohmic metal details of FIG. 4A.

FIG. 6B is a section of the die segment for illustrating details of the gate metal layer of FIG. 3 overlaid on the ohmic metal layer of FIG. 3.

FIG. 7A illustrates source, drain, and gate conductor via 1 details of the die segment of the die of FIG. 1D.

FIG. 7B is a section of the die segment for illustrating details of the via 1 layer of FIG. 3.

FIG. 8A illustrates vias of a via 1 layer of FIG. 7A in the first passivation layer overlaid on ohmic metal fingers and gate metal details of FIG. 6A.

FIG. 8B is a section of the die segment for illustrating details of the via 1 layer of FIG. 3 overlaid on the ohmic metal layer and gate metal layer of FIG. 3.

FIG. 9A illustrates metal 1 details of the die segment of the die of FIG. 1D.

FIG. 9B is a section of the die segment for illustrating details metal 1 layer of FIG. 3.

FIG. 9C shows details of a segment portion of FIG. 9A.

FIG. 10A illustrates metal 1 layer of FIG. 9A overlaid on the details of FIG. 8A.

FIG. 10B is a section of the die segment for illustrating details of the metal 1 layer of FIG. 3 overlaid on the details of FIG. 9B.

FIG. 11A illustrates source, drain, and gate conductor via 2 details of a die segment of the die of FIG. 1D.

FIG. 11B is a section of the die segment for illustrating details of the via 2 layer of FIG. 3.

FIG. 12A illustrates vias of the via 2 layer of FIG. 11A in the second passivation layer overlaid on gate metal details of FIG. 10A.

FIG. 12B is a section of the die segment for illustrating details of vias of the via 2 layer of FIG. 11 overlaid on the metal 1 layer of FIG. 3.

FIG. 13A illustrates metal 2 details of the die segment of the die of FIG. 1D.

FIG. 13B is a section of the die segment for illustrating details of the metal 2 layer of FIG. 3.

FIG. 14A illustrates metal 2 layer of FIG. 13A overlaid on the details of FIG. 12A.

FIG. 14B is a section of the die segment for illustrating details of the metal 2 layer of FIG. 3 overlaid on the details of FIG. 12B.

FIG. 15A illustrates passivation opening 3 details of a die segment of the die of FIG. 1D.

FIG. 15B is a section of the die segment for illustrating details of the passivation 3 opening layer of FIG. 3.

FIG. 16A illustrates an overlay of the passivation opening 3 details of the die segment of FIG. 15A.

FIG. 16B is a section of the die segment for illustrating details of an overlay of the passivation 3 opening layer. 3 on the metal 2 layer of FIG. 3.

FIG. 17 illustrates the passivation opening 3 layer of FIG. 15A for the entire FET die.

FIG. 18A illustrates an overlay of the passivation opening 3 layer of FIG. 17 on the segment of 16A for the entire the FET die.

FIG. 18B illustrates regions of the FET die area.

FIG. 19 illustrates a metal 3 layer, in accordance with aspects of the claimed technology.

FIG. 20 illustrates the metal 3 layer of FIG. 19 showing positioning of the passivation 3 openings with respect to the metal 3 features.

FIG. 21 illustrates a via 3 layer, in accordance with aspects of the claimed technology.

FIG. 22 illustrates an overlay of the via 3 layer of FIG. 17 on the metal 3 layer of FIG. 19.

FIG. 23 illustrates a metal 4 layer 1400, in accordance with aspects of the claimed technology.

FIG. 24 illustrates the metal 4 layer of FIG. 23 showing positioning of the via 3 layer with respect to the metal 4 features.

FIG. 25 illustrates a via 4 layer, in accordance with aspects of the claimed technology.

FIG. 26 illustrates an overlay of the via 4 layer of FIG. 25 on the metal 4 layer of FIG. 23.

FIG. 27 illustrates a metal 5 layer, in accordance with aspects of the claimed technology.

FIG. 28 illustrates the metal 5 layer of FIG. 27 showing positioning of the vias of the via 4 layer with respect to the metal 4 features and metal 5 features.

FIG. 29 is a portion of FIG. 14B for showing cross section positions indicated by lines a-a through f-f.

FIG. 30A illustrates a cross section along line a-a, the length of source fingers.

FIG. 30B shows an enlargement of a portion of the cross section along line a-a of FIG. 30A.

FIG. 31A illustrates a cross section along line b-b, the length of gate fingers.

FIG. 31B shows an enlargement of a portion of the cross section along line b-b of FIG. 31A.

FIG. 32A illustrates a cross section along line c-c, the length of drain fingers.

FIG. 32B shows an enlargement of a portion of the cross section along line c-c of FIG. 32A.

FIG. 33A illustrates a cross section taken along line d-d of FIG. 29.

FIG. 33B shows an enlargement of a portion of the cross section along line d-d of FIG. 33A.

FIG. 34A illustrates a cross section taken along line e-e of FIG. 29.

FIG. 34B shows an enlargement of a portion of the cross section along line e-e of FIG. 34A.

FIG. 35A illustrates a cross section taken along line f-f of FIG. 29.

FIG. 35B shows an enlargement of a portion of the cross section along line f-f of FIG. 34A.

### DETAILED DESCRIPTION

While the disclosed technology is available for embodiment in many different forms, there is shown in the drawings and will herein be described in detail several specific embodiments with the understanding that the present disclosure is to be considered as an exemplification of the principles of the technology and is not intended to limit the technology to the embodiments illustrated.

The terminology used herein is for the purpose of describing particular embodiments only and is not intended to be limiting of the present technology. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used in this specification, the terms “include,” “including,” “for example,” “exemplary,” “e.g.,” and variations thereof, are not intended to be terms of limitation, but rather are intended to be followed by the words “without limitation” or by words with a similar meaning. Definitions in this specification, and all headers, titles and subtitles, are intended to be descriptive and illustrative with the goal of facilitating comprehension, but are not intended to be limiting with respect to the scope of the inventions as recited in the claims. Each such definition is intended to also capture additional equivalent items, technologies or terms that would be known or would become known to a person having ordinary skill in this art as equivalent or otherwise interchangeable with the respective item, technology or term so defined. Unless otherwise required by the context, the verb “may” indicates a possibility that the respective action, step or implementation may be performed or achieved, but is not intended to establish a requirement that such action, step or implementation must be performed or must occur, or that the respective action, step or implementation must be performed or achieved in the exact manner described.

It will be understood that like or analogous elements and/or components, referred to herein, may be identified throughout the drawings with like reference characters. It will be further understood that several of the figures are merely schematic representations of the present technology. As such, some of the components may have been distorted from their actual scale for pictorial clarity.

A FET generally comprises alternating source fingers and drain fingers, and gate fingers disposed between source and drain fingers. Dimensions of the source, drain, and gate fingers may be constrained by interconnections to and from the sources, drains and gates and a breakdown voltage of the FET.

A FET die may contain many small, individual functional building blocks or chiplets. Each chiplet may contain many source, drain and gate fingers. The chiplets may be organized into one or more large individual FETs or one or more pairs configured as a large upper FET connected in a half-bridge configuration to a large lower FET.

FETs for power management, communications and other applications require significant increases in continuous and peak (short duration) current carrying capacity. Methods for increasing current capacity include increasing the gate width per unit area (Wg/A) and, hence, current density of each chiplet; paralleling together multiple chiplets; and reducing their interconnect resistance. Methods for increasing peak current capacity include increasing the thickness and cross sectional area of the FET's metal interconnects to increase the thermal mass/time constant. Increasing current density of the chiplets and a number of chiplets paralleled together may create a need for a low electrical and thermal resistance path from the semiconductor die to its package and printed circuit board.

Conventional FET device fabrication includes producing a fully functional semiconductor die using wafer-level, front end of line (FEOL) process technologies, packaging the semiconductor die using back end of line (BEOL) process technologies, and placing the packaged semiconductor die on a printed circuit board also using BEOL process technologies. In some embodiments the fully functional die is not packaged, and a bare die is mounted onto the PCB or even embedded into the substrate. However unlike the methods described herein, a delineation is made between the FEOL and BEOL processes—the FEOL process technologies, device geometries, design tools, suppliers and manufacturers are different from those used in the BEOL.

FEOL wafer-level processes may employ multiple metal layers, each with progressively increasing thickness and cross section area, to reduce the interconnect resistance, increase the current capacity and bridge the dimensional gap between the fine geometries of the FET's first metal interconnect layer and the course geometries of the FET's last metal layers that connect the FET to its package. However, the FEOL metal layers are expensive and very thin (the total thickness of the FEOL metal layers is typically less than 10 microns), so they have high resistance. The interconnect resistance of large FETs is high due to a need to fully interconnect the many individual FETs that make up the large FET over long distances. Lateral high current flow in thin FEOL metal interconnect layers limits the current carrying capacity and the ability to get the heat out.

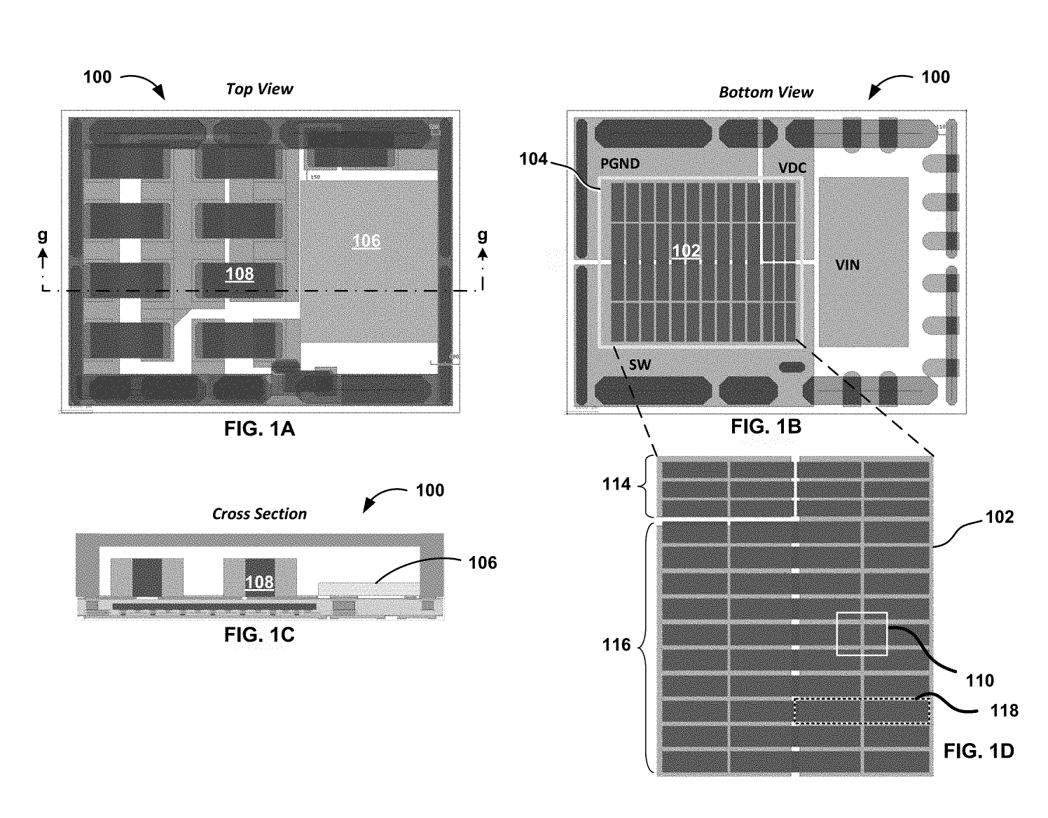

FIG. 1A is a top plan view illustrating a heterogeneously integrated power stage 100, in accordance with aspects of the technology. FIG. 1B is a bottom view of the heterogeneously integrated power stage 100 of FIG. 1A. FIG. 1C is a cross section view of the heterogeneously integrated power stage 100 of FIG. 1A along line g-g. Various regions of the heterogeneously integrated power stage 100 are labeled in FIGS. 1A-1C, including, an embedded die, e.g., a gallium arsenide (GaAs) or silicon (SI) field effect transistor (FET) die 102 fabricated using wafer-level FEOL process technologies embedded in a substrate with metal interconnect layers fabricated using BEOL process technologies, forming a vertically integrated device 104, a driver die 106, and various discrete passive components such as capacitors 108. FIG. 1D is an enlargement of the FET die 102 of FIGS. 1A-1C. The die 102 in FIG. 1D has been rotated 90 degrees counter-clockwise with respect to FIG. 1B for consistency with other illustrations discussed below. A segment 110 of the die 102 is repeated multiple times across the die 102, and will be illustrated and described in further detail elsewhere herein. The FET die 102 may be partitioned by connections in the BEOL into an upper FET 114 and a lower FET 116. The FET die 102 is illustrated as being partitioned into two FETs for simplicity of illustration and clarity, namely the upper FET 114 and lower FET 116. However, the die 102 may be partitioned into more or fewer FETs. In various embodiments, the FET die 102 may be partitioned into 3, 4, 5, 6, 7, 8, or more FETs. A chiplet region 118 may be a repeating subunit. The die 102 may be described as comprising two columns of 13 chiplets 118. In some embodiments, the die 102 is two or more individual die from different FEOL processes (e.g., a GaAs die and a Si die) composed of a number of chiplets that are vertically integrated in to one effective die as described elsewhere herein.

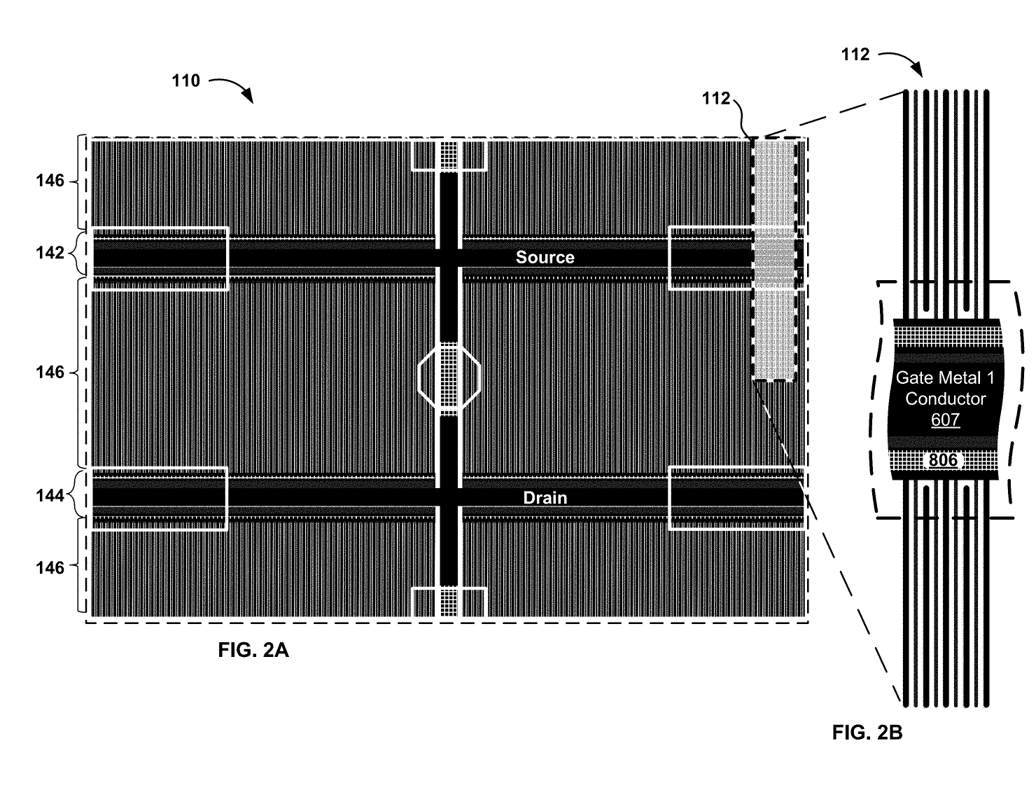

FIG. 2A illustrates general features of the die segment 110 of the die 102 of FIG. 1D. FIG. 2B illustrates general features of a section 112 of the die segment 110 that will be referenced for providing detailed illustration and descriptions of components of the die 102. It should be understood that the section 112 is repeated many times in rows horizontally across the segment, and is provided to simplify the illustrations descriptions of the segment 110. Similarly, rows of the section 112 may be repeated many times vertically to complete the FET die 102. In some embodiments, the repetitions of rows of section 112 alternatively describe source and drain features. For simplicity, the source features are described below. However, the descriptions of the source features are generally representative of the drain features in alternate rows.

As would be understood by persons having ordinary skill in the arts with the present disclosure before them, a FET generally comprises alternating source fingers and drain fingers, and gate fingers disposed between source and drain fingers. Dimensions of the source, drain, and gate fingers are generally constrained by routing of signals and high currents to and from the sources, drains and gates. The spacings between these features may also be constrained by a breakdown voltage of the FET. A person having ordinary skill in the art with the disclosure before them would understand that the die 102 may be considered to be composed of thousands of individual small FETs at the FEOL level, that may be organized into one large FET, or a large upper FET and a large lower FET (or multiple large FETs, eg., 3, 4, 5, 6, 7, 8 or more large FETs) using the BEOL connections. For example, the thousands of individual small FETS fabricated at the FEOL level can then be connected in 1 large FET, 2 large FETs etc., using the BEOL levels. In some embodiments, a decision whether to fabricate 1, 2, or more large FETs and how to configure the BEOL layers can be made before or after completing the FEOL fabrication of GaAs or SI die. Thus, the exact same die can be taken from a wafer upon completing FEOL processing and can be embedded multiple different ways, while deciding how to organize it after fabrication of the die is complete. Furthermore, a standardized die may be processed in the FEOL to optimize the die for yield, and then a wide range of products, each having a desired different performance may be realized utilizing an inexpensive BEOL processing to integrate one or more die together.

The segment 110 may be described as having non-active areas 142 and 144, and active areas 146. The active areas include the sources, drains, and gates.

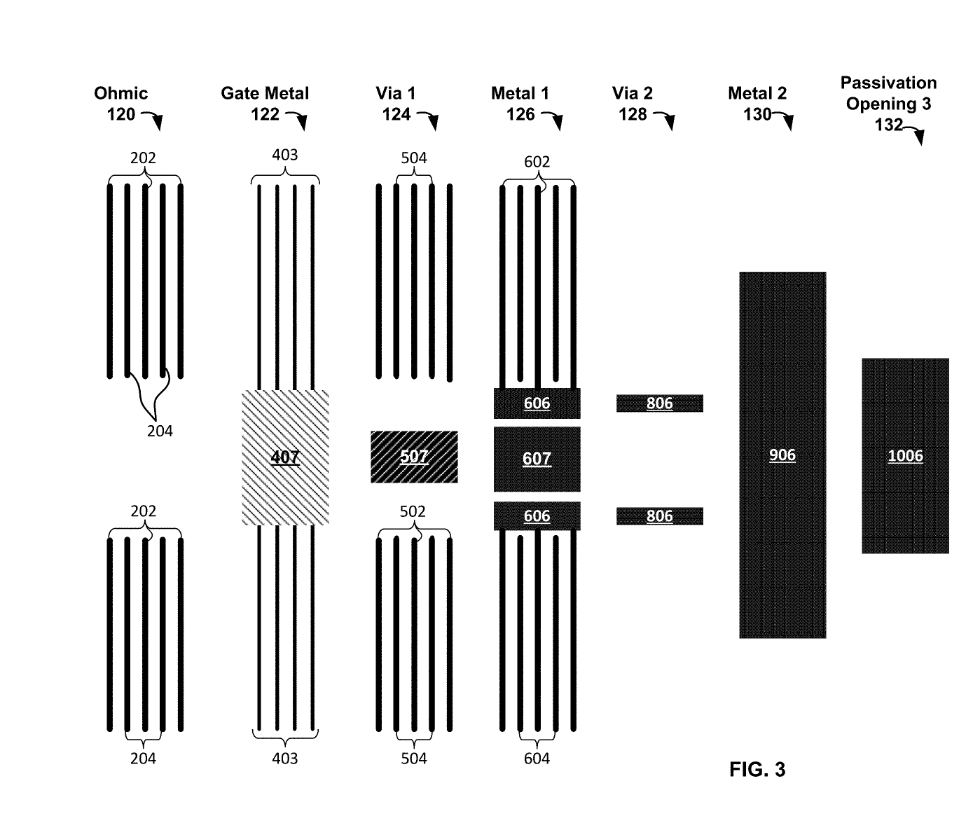

FIG. 3 illustrates separate layers of the section 112 of FIG. 2B. These section layers, which are illustrated side-by-side, may be overlaid to form the section 112 and are repeated across the die segment 110. The section layers include an ohmic layer 120, a gate metal layer 122, a via 1 layer 124 and a metal 1 layer 126.

A first passivation layer may be disposed above the ohmic layer 120 and gate metal layer 122 and below the metal 1 layer 126 to isolate the metal 1 layer 126 from the gate metal layer 122 and the ohmic layer 120. Vias of the via 1 layer 124 may provide communication through the first passivation layer from the metal 1 layer 126 to the gate metal layer 122 and ohmic layer 120.

For example, gate conductor vias 507 of the via 1 layer 124 may provide connection through a first passivation layer from a gate metal 1 conductor 607 of the metal 1 layer 126 to a gate conductor 407 of the gate metal layer 122. Similarly, drain finger vias 504 of the via 1 layer 124 may provide connection through the first passivation from drain metal 1 fingers 604 of the metal 1 layer 126 to ohmic drain fingers 204 of the ohmic layer 120.

Similarly, source finger vias 502 of the via 1 layer 124 may provide connection through the first passivation from source metal 1 fingers 602 of the metal 1 layer 126 to ohmic source fingers 202 of the ohmic layer 120. The first passivation layer may isolate source metal 1 conductors 606 from a gate conductor 407. It is noteworthy that a thin via 1 layer 124 may contribute to a reduction of dimensions of the via features that can be fabricated over the source and drain ohmic metal fingers 202/204, thus, permitting a reduction in dimensions of the source/drain fingers. In some embodiments, the via 1 layer 124 is very thin, e.g., less than 0.1, 0.25, 0.5, 1.0 microns. For example a thin nitride may be used for making small via features of the via 1 layer 124 and/or contacts. This may serve to minimize source and drain finger width. As a result, the thinner passivation layer enables the fabrication of a narrower source/drain, while a thicker passivation layer results in wider source/drain sizes.

The section layers of FIG. 3 further include a via 2 layer 128 and a metal 2 layer 130. A second passivation layer may be disposed between the metal 2 layer 130 and the metal 1 layer 126 to isolate the two layers. Source via 2 interconnects 806 of the via 2 layer 128 may serve as an interconnection through the second passivation layer from a source metal 2 conductor 906 of the metal 2 layer 130 to the source metal 1 conductors 606 of the metal 1 layer 126. The source interconnections through the second passivation layer may be disposed in the source non-active region 142 without providing interconnections such as vias in the active region 146.

Similarly, drain conductor vias (not shown in FIG. 3) of the via 2 layer 128 may provide communication through the second passivation layer from a drain metal 2 conductor (not shown) of the metal 2 layer 130 to drain metal 1 conductors (not shown) of the metal 1 layer 126. The section layers of FIG. 3 further include a third passivation layer disposed on the metal 2 layer 130 and a passivation opening layer 132, as discussed in further detail elsewhere herein. The drain interconnections through the second passivation layer may be disposed in the drain non-active region 144 without providing interconnections such as vias in the active region 146.

A third passivation may be disposed between the second metal layer 130 and a third metal layer (illustrated and described elsewhere herein). The third passivation layer may separate front end of line (FEOL) processes and back end of line (BOEL) processes. Openings through the third passivation layer may form a passivation 3 opening layer 132 to provide communication through the third passivation layer between the metal 3 layer and the metal 2 layer.

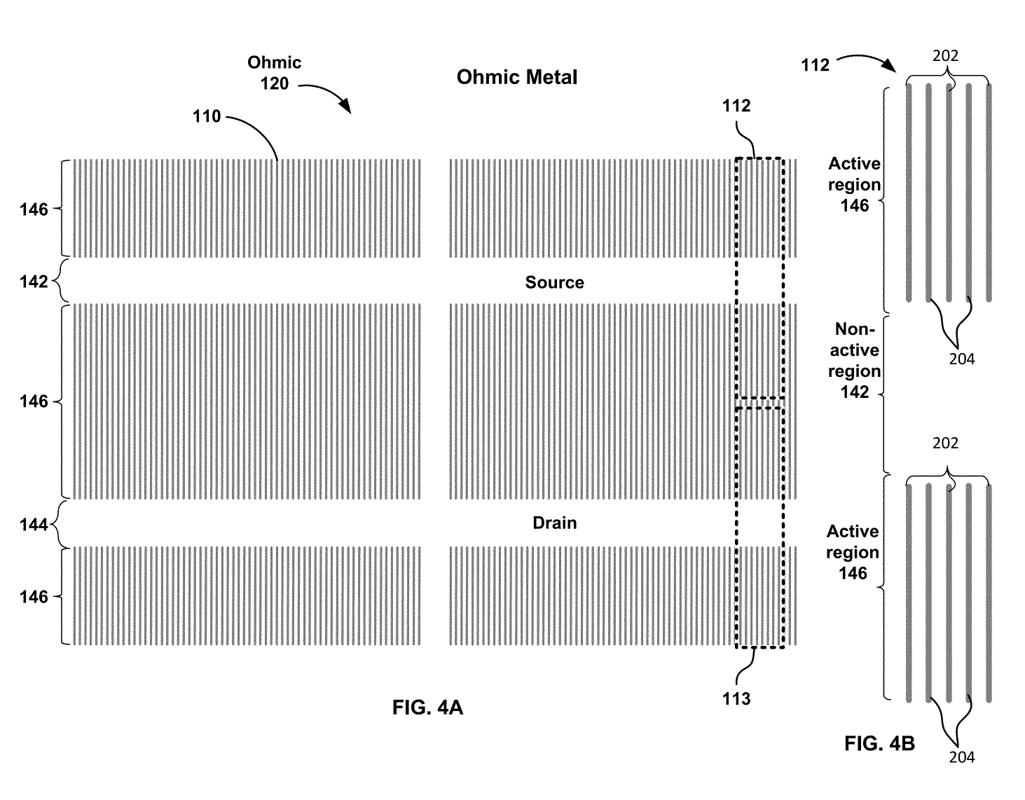

FIG. 4A illustrates ohmic metal details of the die segment 110 of the die 102 of FIG. 1D. FIG. 4B is a section 112 of the die segment 110 for illustrating details of the ohmic layer 120 of FIG. 3. The source fingers 202 and drain fingers 204 of the ohmic layer 120 may be disposed in an active area 146 of the segment 110 as illustrated in FIGS. 4A and 4B. Non-active areas 142 and 144 of the segment 110 are illustrated in FIGS. 4A and 4B. Generally source signals and current may be conducted in non-active areas 142 and drain signals and current may be conducted in non-active areas 144. FIG. 4A also includes a section 113, which is analogous to section 112. However, it may be appreciated that section 113 differs from section 112 in that drain features are generally in contact with a drain metal 1 conductor 608 (illustrated elsewhere herein) of the non active region 144 in section 113, where source features are in contact with source metal 1 conductor 606 in section 112. For simplicity, source features are generally illustrated and described with respect to the section 112 and non-active area 142. However, it may be appreciated that the illustrations and descriptions may be applied to drain features in section 113 and the non-active area 144.

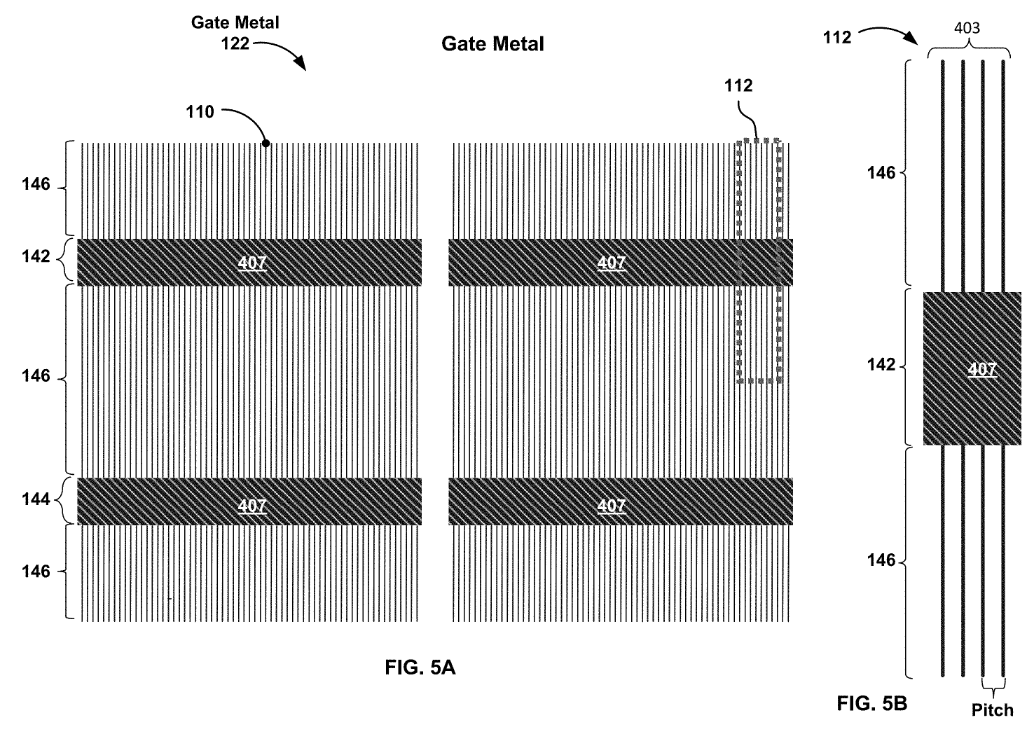

FIG. 5A illustrates gate metal details of the die segment 110 of the die 102 of FIG. 1D. FIG. 5B is a section 112 of the die segment 110 for illustrating details of gate metal layer 122 of FIG. 3. The gate metal layer may be disposed on the GaAs die substrate. In some embodiments, there is a thin nitride layer (not illustrated) below the gate metal layer 122 for isolating the gate metal from the substrate. The nitride layer may serve to reduce leakage current. The gate conductor 407 connects the gate fingers 403 together. It may be appreciated that the gate fingers 403 may be connected using the gate metal conductor 407, and without using gate vias disposed in the active area 146. Instead, gate signals may be routed beneath the source/drain conductors 606/608. Moreover, the gate metal conductor 407 disposed over the non-active region may accommodate a much larger via than could be disposed over the gate fingers 403. This permits conducting much larger gate current through the gate metal conductor 407 than could be conducted using vias in the active region over the gate fingers 403. As discussed above, the gate metal conductor 407 is used to route gate signals underneath the source/drain conductors to the gate fingers 403. This is generally a unique configuration compared to GaAs fabrication standards practiced at GaAs foundries. However, the process may be used in Si foundries.

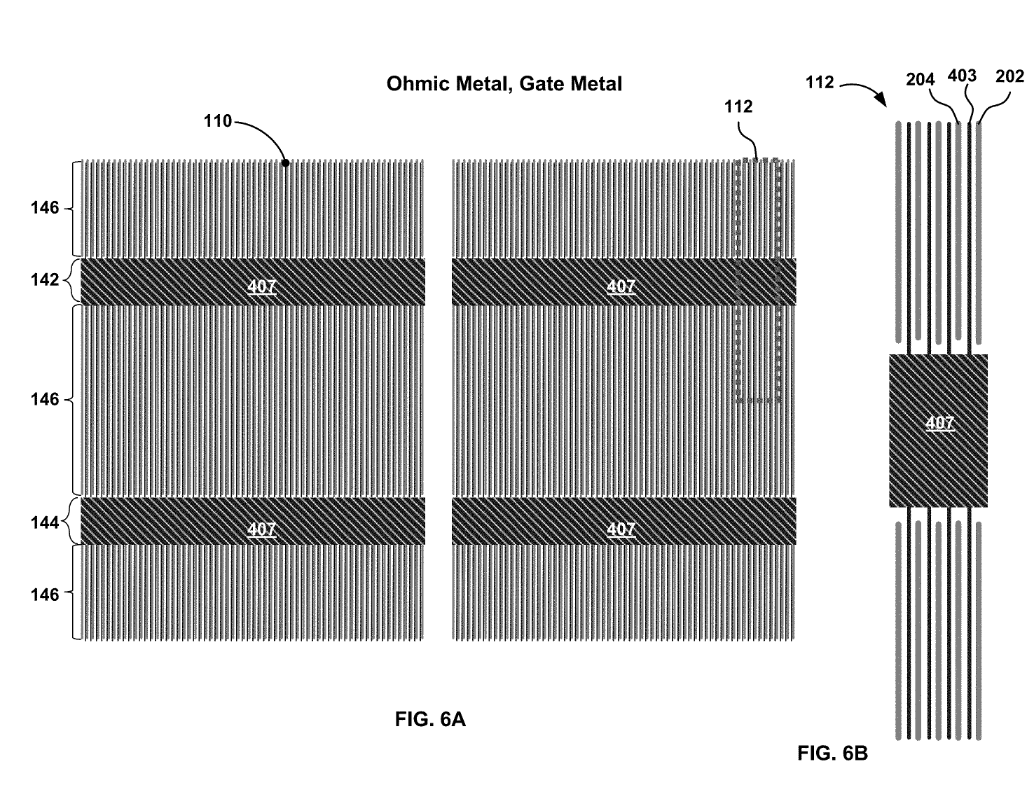

FIG. 6A illustrates gate metal of FIG. 5A overlaid on the ohmic layer 120 details of FIG. 4A. FIG. 6B is a section 112 of the die segment 110 for illustrating details of the gate metal layer 122 of FIG. 3 overlaid on the ohmic layer 120 of FIG. 3. The gate fingers are illustrated as being disposed between adjacent source fingers 202 and drain fingers 204 in the detail of FIG. 6B. The first passivation layer (not illustrated) may be disposed over the layers illustrated in FIGS. 4-6. Vias through the first passivation layer may provide for communication of signals and current through the first passivation layer, as described below.

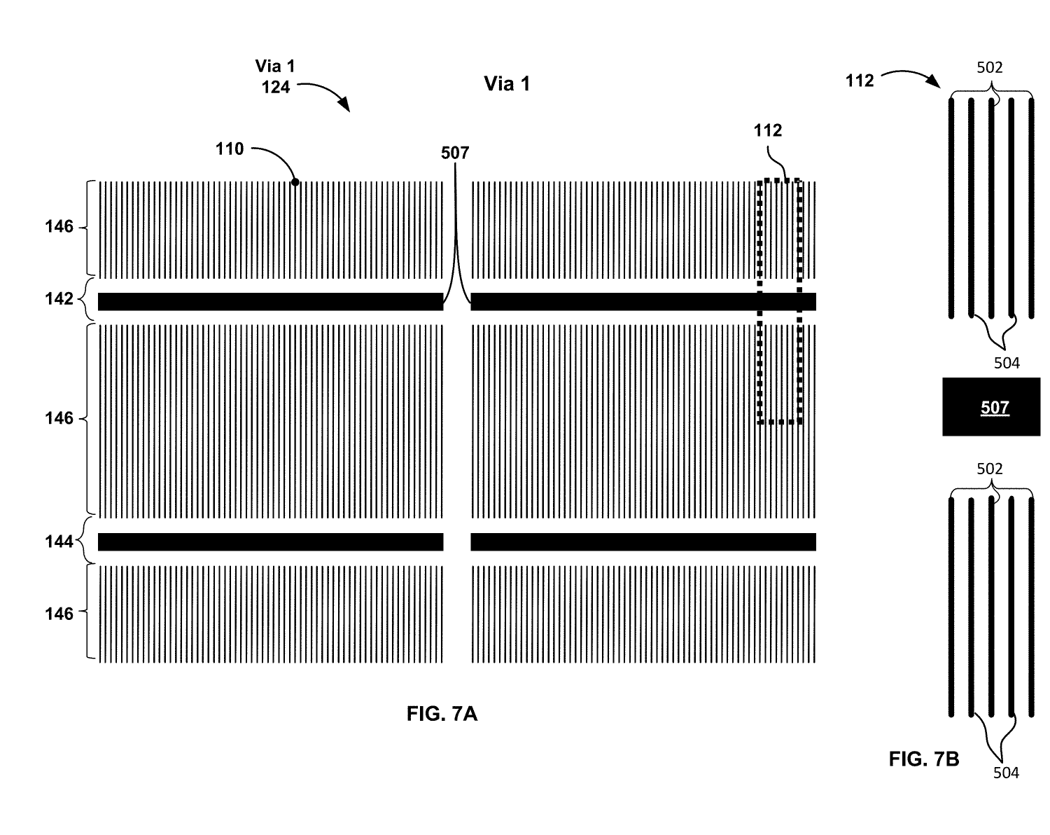

FIG. 7A illustrates source, drain, and gate conductor via 1 details of the die segment 110 of the die 102 of FIG. 1D. FIG. 7B is a section 112 of the die segment 110 for illustrating details of the via 1 layer 124 of FIG. 3. A gate conductor via 507 may provide gate voltage to be communicated through the first passivation layer to the gate conductor 407.

Source finger vias 502 may provide contact between the source metal 1 fingers 602 and the source ohmic fingers 202. Similarly, drain finger vias 504 may provide contact between the drain metal 1 fingers 604 and the drain ohmic fingers 204. It may be appreciated that a thin passivation layer allows for a small via and hence smaller ohmic and metal1 layers in regards to x and y dimensions. This allows the gate pitch to be as small as possible. The pitch may be equal to the width of the source/drain plus the spacing required between the source/drain ohmic region and the gate. The source/drain to gate spacing may be dependent on the breakdown properties, and so the thin passivation allows for a more narrow source/drain and hence reduces the pitch. The pitch may be reduced even more as a result of not making a connection between metal 2 and metal 1 over the active region. For example, a source/drain may be 1.4 um wide. However, if the connection were made over the active area that width would have to increase from 1.4 um to Sum. As a result, the present pitch of 3.3 um would more than double to 6.9 um. The thickness of the metal 1 may be made as thick as possible for the given pitch so as to minimize the resistance of the source/drain fingers and, hence, allow for wider FETs which in turn improves the Wg/A at the expense of switching time.

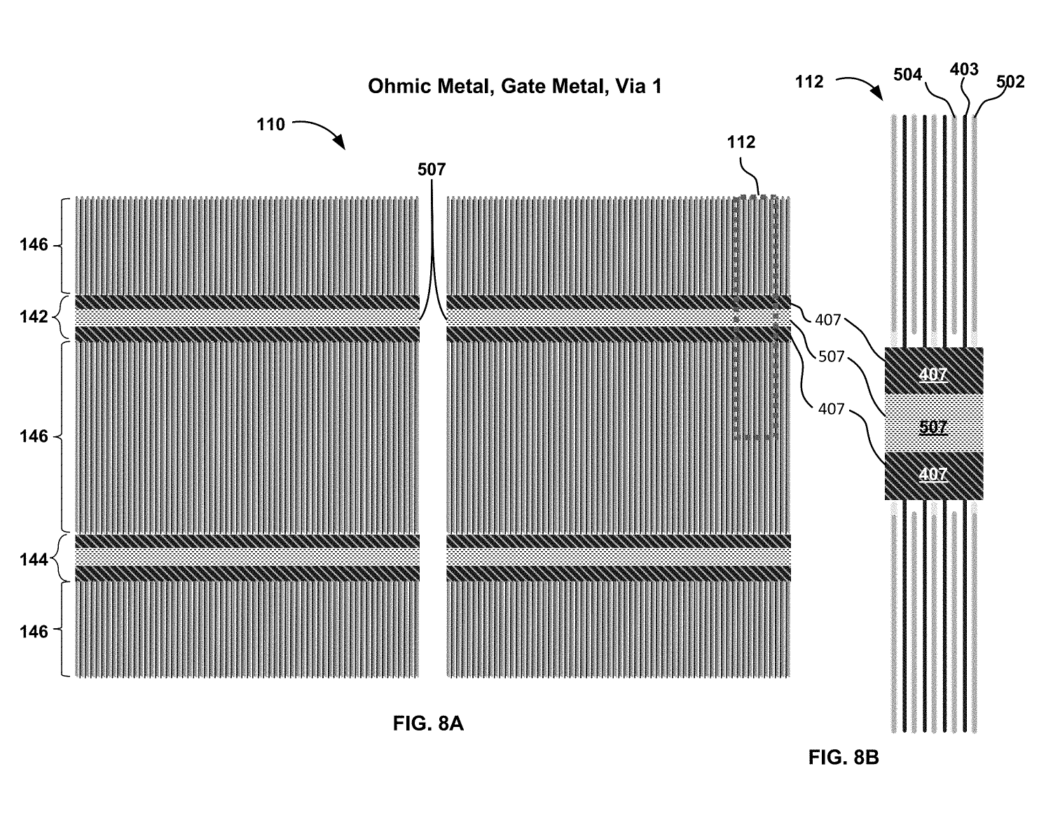

FIG. 8A illustrates vias of the via 1 layer 124 of FIG. 7A in the first passivation layer overlaid on ohmic fingers and gate metal details of FIG. 6A. FIG. 8B is a section 112 of the die segment 110 for illustrating details of the via 1 layer 124 of FIG. 3 overlaid on the ohmic layer 120 and gate metal layer 122 of FIG. 3.

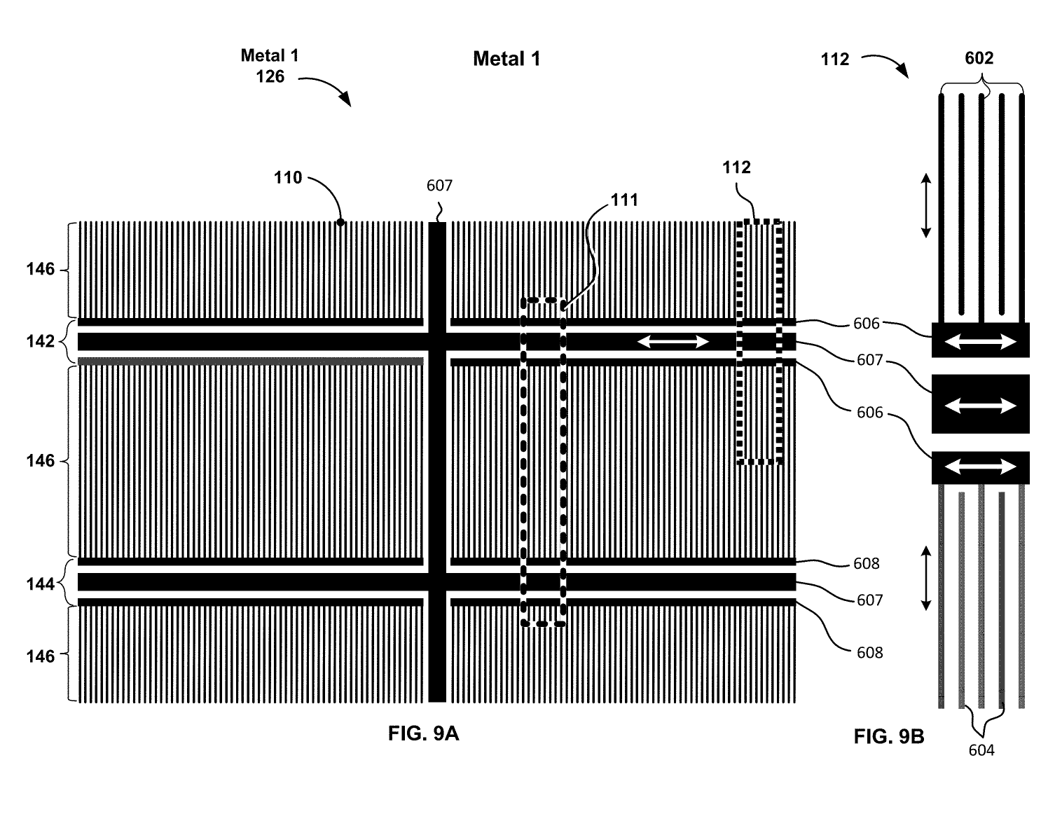

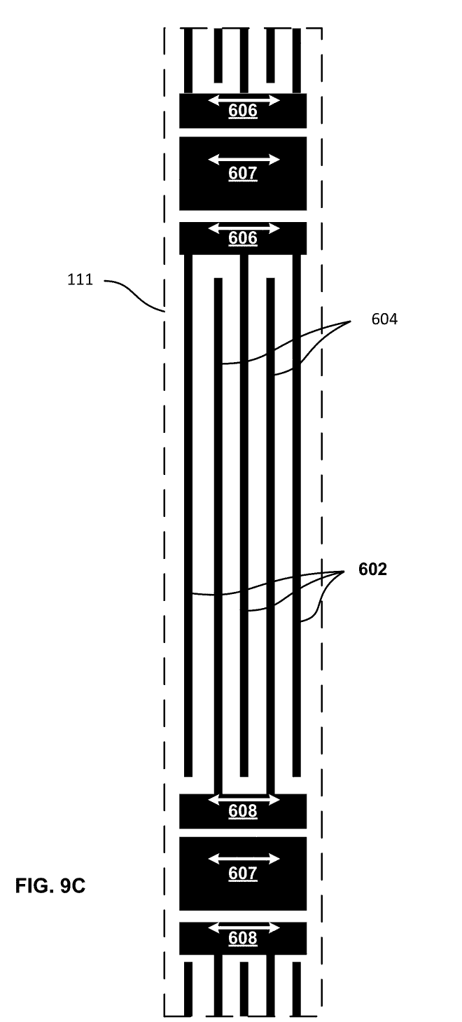

FIG. 9A illustrates metal 1 details of the die segment 110 of the die 102 of FIG. 1D. FIG. 9B is a section 112 of the die segment 110 for illustrating details metal 1 layer 126 of FIG. 3. The metal 1 layer serves primarily to provide interconnection to the source fingers, drain fingers and gate metal. The source metal 1 fingers 602 and drain metal 1 fingers 604 are disposed to connect through the respective source vias 502 and drain vias 504, directly to the respective source ohmic fingers 202 and drain ohmic fingers 204.

The source metal 1 conductor 606 is disposed on the first passivation layer and separated from the underlying gate metal conductor 407 by the first passivation layer. However, the source metal 1 conductor is contiguous with the source metal 1 fingers 602.

Lateral current flowing through the source metal 1 fingers (thin vertical arrows) may encounter relatively high resistance in the active area 146 because individual source fingers may be relatively thin and narrow for packing more source fingers into the active area. However, it may be appreciated that the current through individual fingers may be relatively low, and packing more source fingers into the active area provides for additional source fingers to conduct the current in parallel. Moreover, the distance that the lateral current flows in the active area 146 through the source fingers may be relatively short. In some embodiments, the distance of the lateral current flow through the source and/or drain fingers is less than about 200 microns.

FIG. 9C shows details of a segment portion 111 of FIG. 9A. Segment portion 111 differs from segment portion 112 in that segment portion 111 spans two adjacent non-active areas 142 and 144. The two non-active areas include both source metal 1 conductor 606, which is contiguous with source metal 1 fingers 602 but not contiguous with drain metal 1 fingers 604, and drain metal 1 conductor 608, which is contiguous with drain metal 1 fingers 604 but not source metal 1 fingers 602. Since the current generally flows vertically into metal 2 and substantially then up into the thick BEOL layers the metal source/drain conductors 606 and 608 can remain relatively small and still handle large currents.

Interconnections to the source metal 1 fingers 602 and ohmic fingers 202 may be provided through the source metal 1 conductor 606, which is substantially wider than the source metal 1 fingers 602. Moreover, the source metal 1 conductor 606 is disposed above the gate metal (separated from the gate metal by the first passivation layer) and outside the active area 146 and within the non-active area 142. Thus, lateral interconnect current flowing through the source metal 1 conductor 606 (thick horizontal arrows) encounters low resistance and may be substantially higher than the source fingers. However, the bulk of the current in these conductors flows vertically up into metal 2, and there is little lateral current flow. Any lateral current flow happens at the ends of the conductor. In some embodiments, the metal 1 layer 126 is fabricated using a layer of copper about 2 microns thick. Other metals and/or thickness may be used. Examples include gold, aluminum, and/or the like. For example, gold at a thickness of 1 micron may be used.

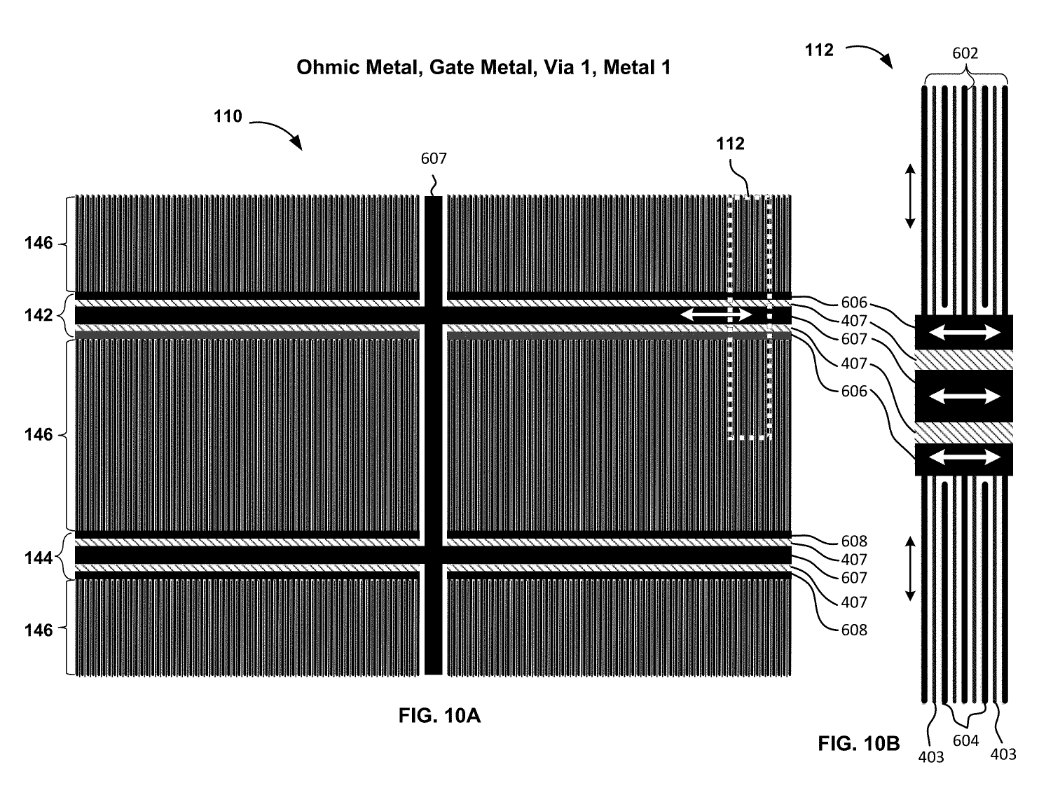

FIG. 10A illustrates metal 1 layer of FIG. 9A overlaid on the details of FIG. 8A. FIG. 10B is a section 112 of the die segment 110 for illustrating details of the metal 1 layer 126 of FIG. 3 overlaid on the details of FIG. 9B.

Interconnections to the gate metal fingers 403 may be provided through the gate metal 1 conductor 607, through the first passivation layer by way of the gate via 507 to the gate metal conductor 407, which is substantially wider than the gate metal fingers 403. Moreover, the gate metal 1 conductor 607 is disposed outside the active area 146 and within the non-active area 142. The second passivation layer (not illustrated) may be disposed over the metal 1 layer illustrated in FIG. 10. Vias in the second passivation layer may provide for communication of signals and current through the second passivation layer, as described below.

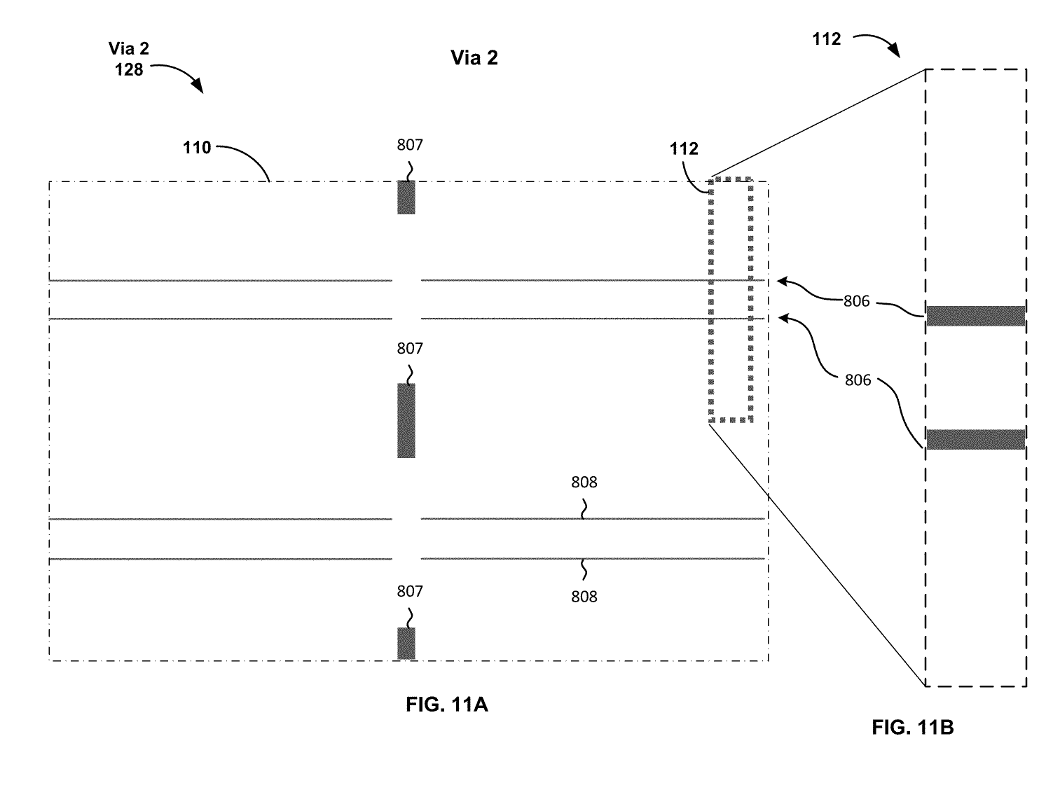

FIG. 11A illustrates source, drain, and gate conductor via 2 details of the die segment 110 of the die 102 of FIG. 1D. FIG. 11B is a section 112 of the die segment 110 for illustrating details of the via 2 layer 128 of FIG. 3. Extent of the die segment 110 is represented by a dotted line, which is not part of the device. Similarly, extent of the section 112 are represented by dotted line, which is not part of the device.

A gate via 2 interconnect 807 may provide for gate voltage to be interconnected through the second passivation layer from the gate metal 2 conductor 907 to the gate metal 1 conductor 607. Source via interconnects 806 in the second passivation layer may provide interconnection between the source metal 2 conductor 906 and the source metal 1 conductor 606, which is in turn connected to the source metal 1 fingers 602 disposed on the source ohmic fingers 202. Similarly, drain vias 808 may provide contact between the drain metal 2 conductor 908 and the drain metal 1 conductor 608, which is in turn connected to the drain metal 1 fingers 604 disposed on the drain ohmic metal fingers 204.

The gate via 2 interconnect 807 may be sized relatively small to accommodate other features, e.g., vias 1006 and/or 1008. Typical dimensions for the gate via 2 interconnect 807 may be 2-4 microns thick, by 10-20 microns wide by 20-44 microns long. The gate via 2 interconnect 807 may also serve to move heat up and out of the FEOL layers.

The source via 2 interconnect 806 functions as both a lateral and vertical interconnect. The majority of current flows vertically up into the thick metal 2 and then up into even thicker BEOL metal layers. Some might call this a via. However, it is noteworthy that the “via” extends continuously for substantially all of the source/drain metal1 conductor length. In doing so, the “via” effectively becomes a lateral interconnect, rather than a traditional vertical via and increases the thickness of the metal1 conductor for lateral current flow. The source via 2 interconnect 806 may also be sized for effective deposit of substantial amounts of metal such as copper within the interconnect, even using FEOL processes. At the ends of the conductor, there may be some lateral current flow through the metal 1 conductors and in that case the via acts as a lateral interconnect. In addition to the 2 um metal 1 layer, there is additional 3-4 um of the via plus another 4 um of the metal 2 layer for a total of 9-10 um, instead of just the 2 um in parallel with 4 um with intermittent pieces of 3-4 um as is found in typical FEOL process. The drain via 2 interconnect 808 is similarly sized and disposed on the drain metal 1 conductor 608. Thus, the source via 2 interconnect 806 may conduct substantially more current than a typical via. The source via 2 interconnect 806 may also serve to move heat up and out of the FEOL layers.

In some embodiments, a via interconnect such as described with respect to the source/drain/gate via 2 interconnects, may be described as a series of vias that are connected to form a continuous line of contiguous vias. Thus, the via interconnect may be described as a long interconnect bar, rather than many discreet vias. Whereas the conventional practice is to constrain the width of vias to comparative smaller sizes and the length to the same order of magnitude of the widths, the via interconnect may have a length that is orders of magnitude greater than the width. These longer dimensions of the source/drain via 2 interconnect, and more particularly lengths that are orders of magnitude greater than widths, contribute to conducting substantially more current and heat though the FET. Moreover, a via interconnect that forms a single long bar disposed along substantially the entire length the source/drain metal 1 conductor virtually eliminates all lateral conduction of current between discreet vias within the source/drain metal 1 conductor and within the source/drain metal 2 conductor.

It is noteworthy that the source, drain, and gate via 2 interconnects may be sized for conducting large currents and heat by virtue of being positioned almost entirely in the non-active region without impacting the gate pitch. Its sizing impact on Wg/A is second order. Furthermore, this positioning within the non-active region permits fabricating active regions of source/drain/gate fingers without positioning any vias within active region over these features. Having no vias over the metal 1 layer of the active region permits reducing the source-drain pitch by fabricating source/drain fingers having substantially smaller dimensions than would be feasible if vias were used to remove current from the source/drain metal 1 layer in the active region.

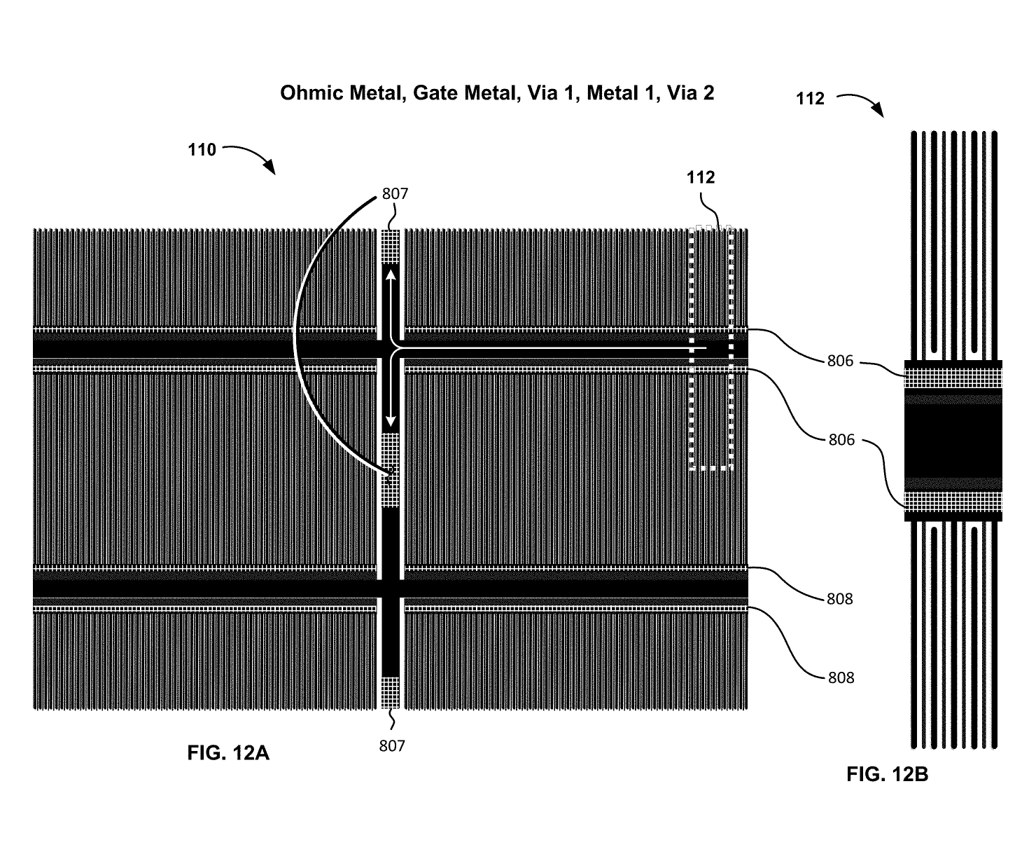

FIG. 12A illustrates an example of how the vias of the via 2 layer 128 of FIG. 11A in the second passivation layer may be overlaid on the metal details of FIG. 10A. FIG. 12B is a section 112 of the die segment 110 for illustrating details of how the vias of the via 2 layer 128 of FIG. 11 may be overlaid on the metal 1 layer 126 of FIG. 3.

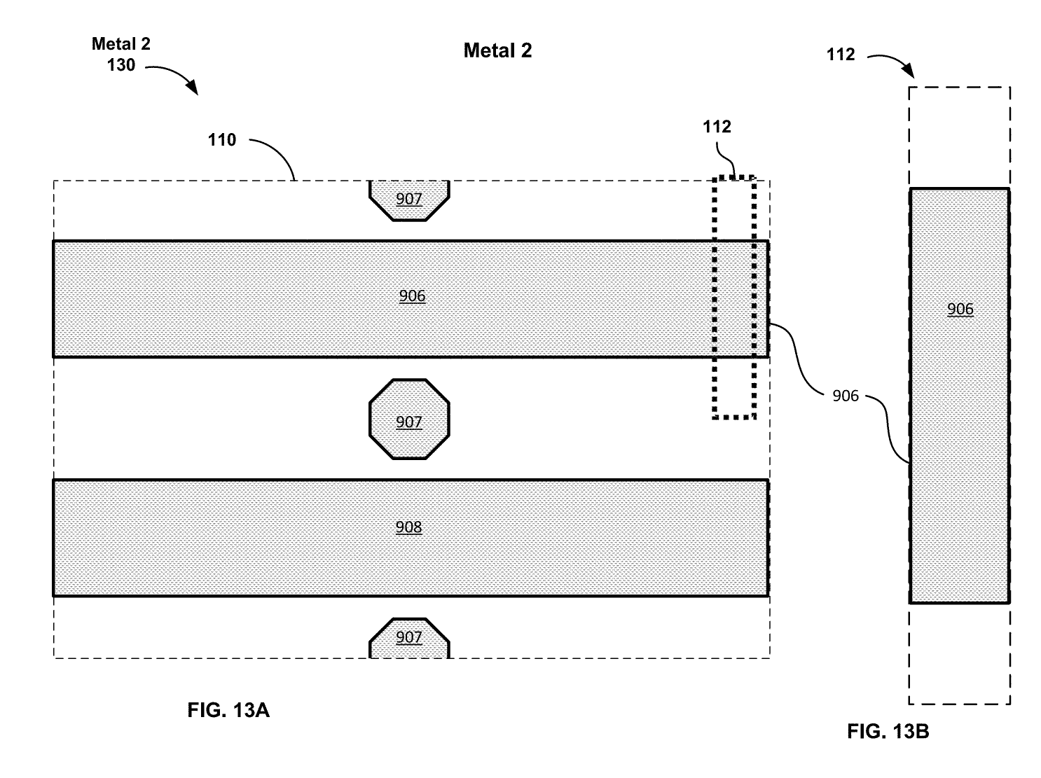

FIG. 13A illustrates metal 2 details of the die segment 110 of the die 102 of FIG. 1D. FIG. 13B is a section 112 of the die segment 110 for illustrating details of the metal 2 layer 130 of FIG. 3. Extent of the die segment 110 is represented by a dotted line, which is not part of the device. Similarly, extent of the section 112 is represented by dotted line, which is not part of the device. The metal 2 layer includes source metal conductors 906, gate metal 2 conductors 907, and drain metal 2 conductors 908.

Like the metal1 source/drain conductors, the metal 2 layer serves primarily to provide a vertical interconnection from a relatively thin metal 1 layer to a substantially thicker metal 3 layer (illustrated and discussed in more detail elsewhere herein). This may serve to bridge a dimensional gap between the metal 1 and metal 3 layers. In some embodiments, the metal 2 is produced using a BEOL process, e.g., when the BEOL process can provide interconnection to fine geometries of FEOL via 2 layers. Otherwise, the metal 2 layer may be produced using FEOL process. In essence, the amount of processing done in the FEOL process may be the minimum required to organize the layout to conform to ground rules of the BEOL process. In some embodiments no actual metal layers need to be processed in the FEOL process. This may be referred to as embedded in interconnect. In some embodiments, metal 2 is fabricated using copper having a thickness of about 4 microns. The metal 2 layer includes source metal conductors 906, gate metal 2 conductors 907, and drain metal 2 conductors 908. Simply put, because metal 2 primarily provides vertical connection, it can be thinner than one might expect when used to carry large currents. Since it does not have to be thick, the result is the potential to lower FEOL costs and simplify FEOL processing.

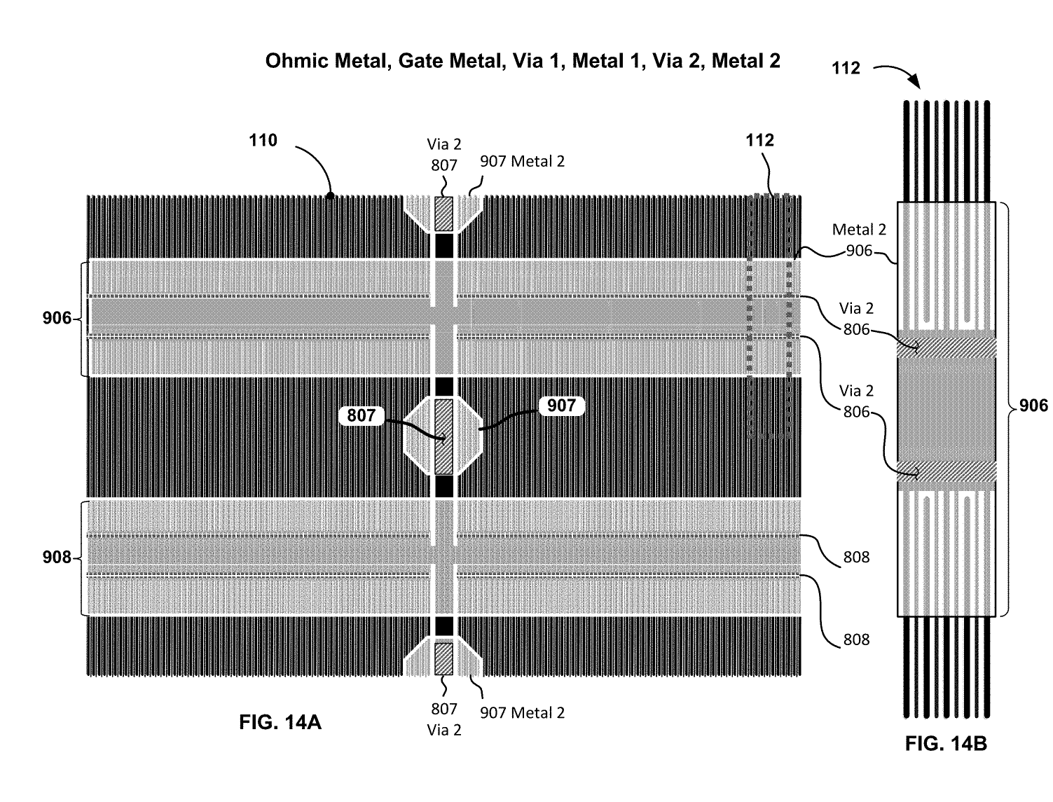

FIG. 14A illustrates metal 2 layer of FIG. 13A overlaid on the details of FIG. 12A. FIG. 14B is a section 112 of the die segment 110 for illustrating details of the metal 2 layer 130 of FIG. 3 overlaid on the details of FIG. 12B. Note that while details of the metal 2 layer 130 are shown for the source metal 2 conductor 906 in FIG. 14B, the details for drain metal 2 conductor 908, which are similar but redundant, are omitted for simplicity.

The source metal 2 layer is disposed on the second passivation layer, which generally separates the metal 2 from the underlying metal 1 except at the vias in the second passivation layer. The source metal 2 conductor 906 may be connected through the second passivation layer by way of the source via 2 interconnect 806 in the via 2 layer 128. Similarly, the drain metal 2 conductor 908 may be connected through the second passivation layer by way of the drain via 808 in the via 2 layer 128. Also, the gate metal 2 conductor 907 may be connected through the second passivation layer by way of the gate via 807 in the via 2 layer 128. The third passivation layer (not illustrated) may be disposed over the metal 2 layer illustrated in FIG. 14. Passivation openings in the third passivation layer may provide for communication of signals and current through the third passivation layer, as described below.

It is noteworthy that the second passivation layer (via 2 layer 128) isolates the entire the active region 146 from the metal 2 layer 130 and subsequent metal layers deposited directly on the die 102 using the BEOL processes. Thus, features of the metal 2 layer that extend into the active region 146 because they are larger than the non-active region, may be fabricated on the second passivation region. While the second passivation layer isolates metal 2 from the active region, passivation layer 2 and the final FEOL passivation layer together isolate the active area from BEOL metal layers. As a result, the first BEOL metal layer may be substantially removed from metal 1, reducing the parasitics. That is one reason to route the gate predominately using the first BEOL metal layer. There may be less coupling capacitance and the metal may be thicker, which may provide lower resistance and result in faster switching speeds. This may be a desirable result in a power device. Furthermore, utilizing the BEOL metal layers may result in a smaller die than if the layers were fabricated using the FEOL metal layers.

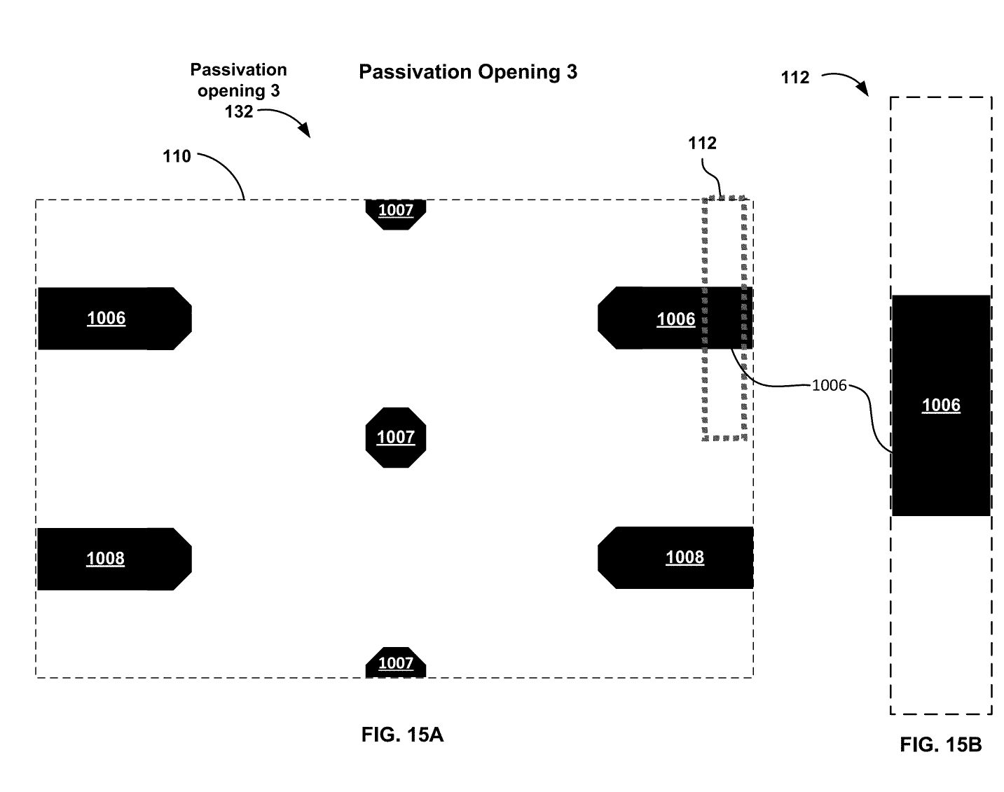

FIG. 15A illustrates passivation opening 3 details of the die segment 110 of the die 102 of FIG. 1D. FIG. 15B is a section 112 of the die segment 110 for illustrating details of the passivation 3 opening layer 132 of FIG. 3. The passivation 3 opening layer 132 includes source vias 1006 for communicating signals and current between the source metal 3 conductor 1106 and the source metal 2 conductor 906; drain vias 1008 for communicating signals and current between the drain metal 3 conductor 1108 and the drain metal 2 conductor 908; and gate vias 1007 for communicating signals and voltage between the gate metal 3 conductor 1107 and the gate metal 2 conductor 907.

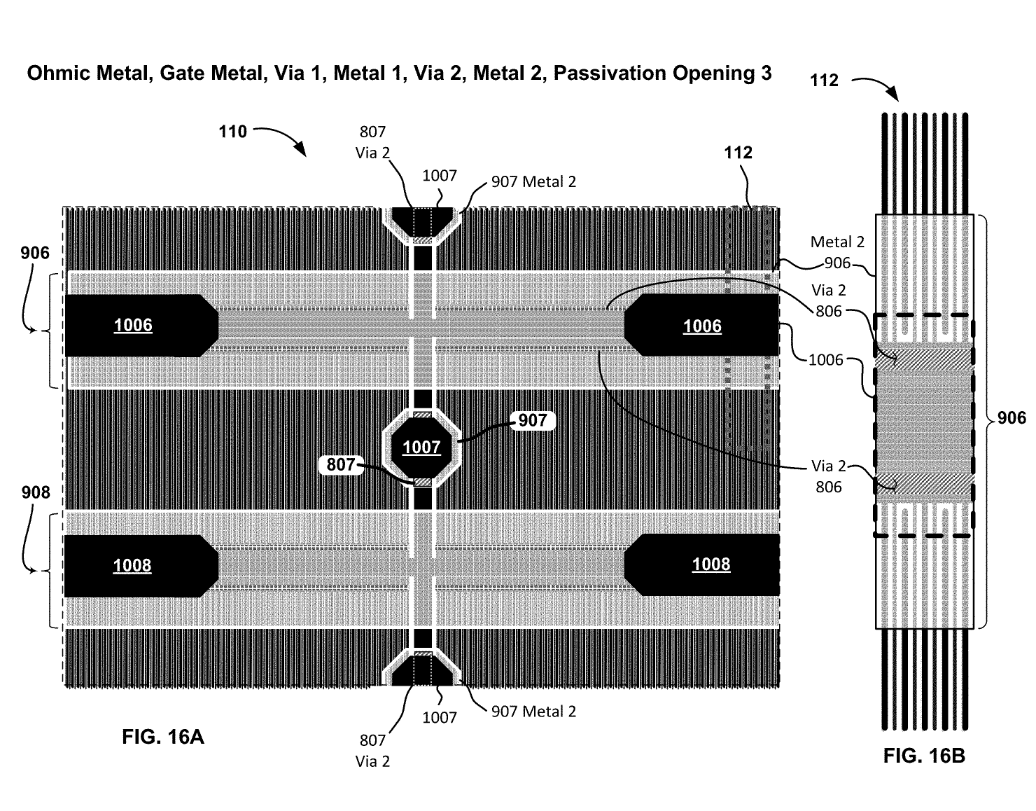

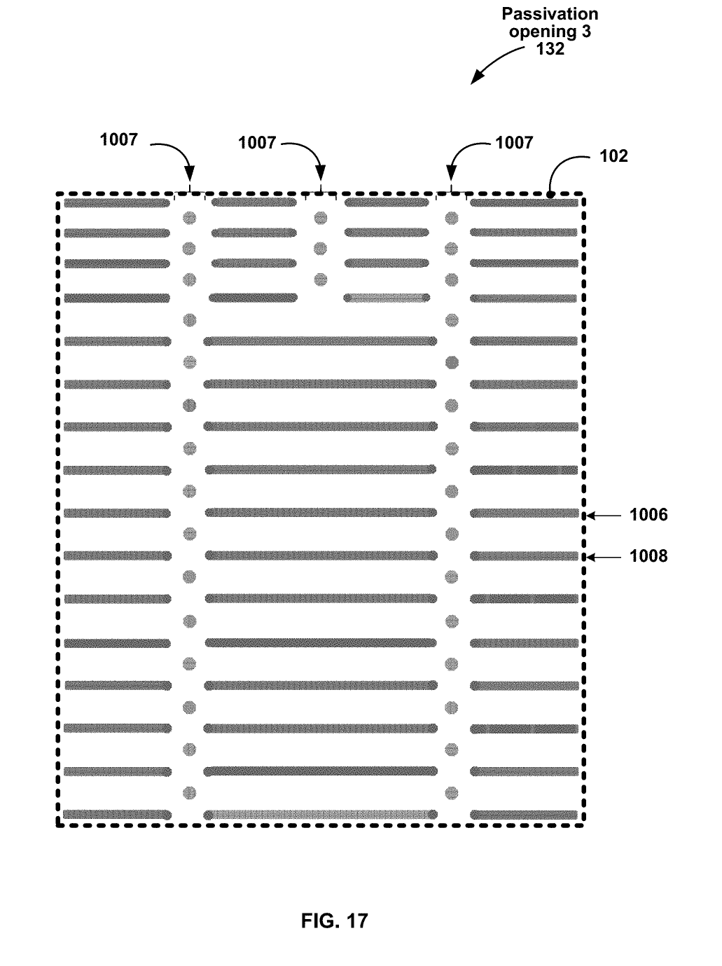

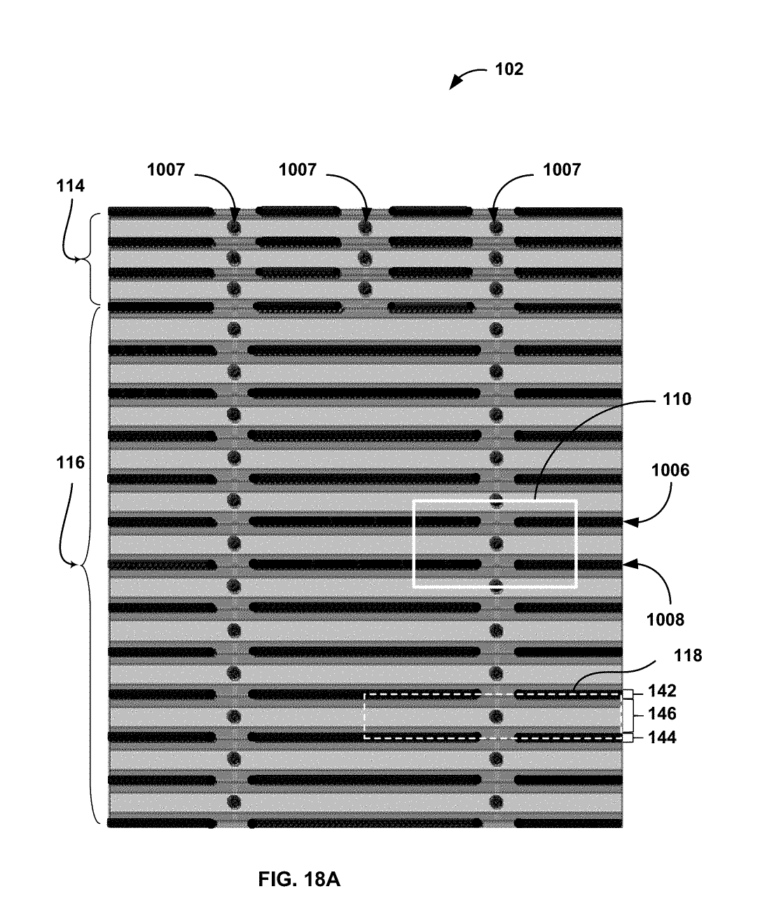

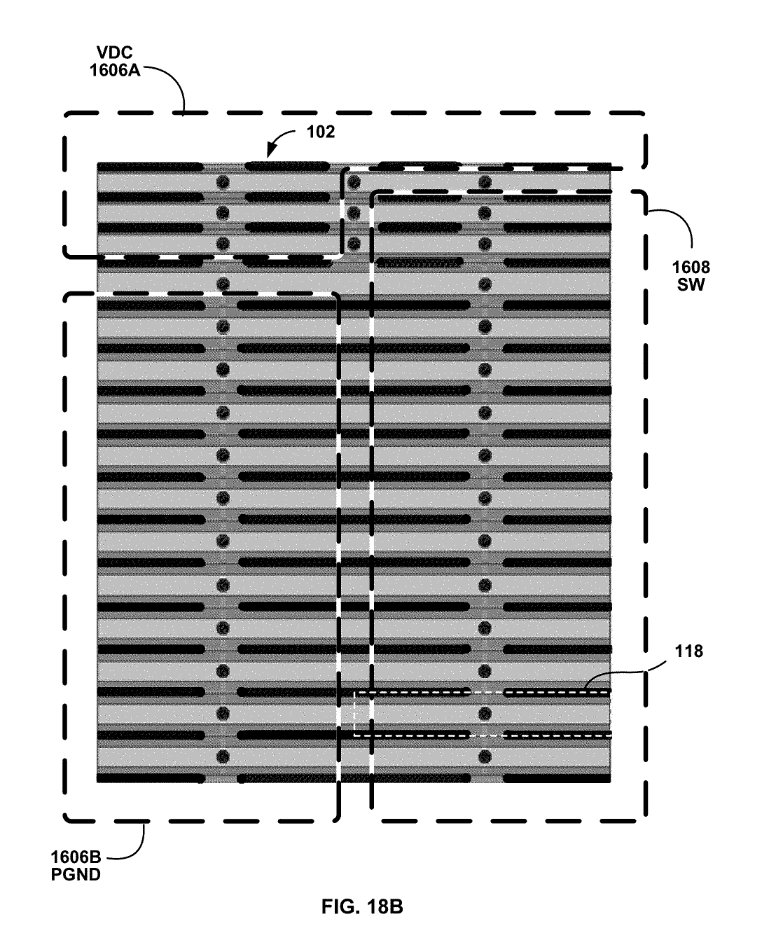

FIG. 16A illustrates the passivation opening 3 details of the die segment 110 of FIG. 15A overlaid onto the details of FIG. 14A. FIG. 16B is a section 112 of the die segment 110 for illustrating details of an overlay of the passivation 3 opening layer 132 on the metal 2 layer 130 of FIG. 3. FIG. 17 illustrates the passivation 3 opening layer 132 of FIG. 15A for the entire FET die 102. FIG. 18A illustrates an overlay of the passivation 3 opening layer 132 of FIG. 17 on the segment 110 of 16A for the entire the FET die 102. In some embodiments, the FET die 102 is not fully functional at this point. While all the gates are fully connected using the FEOL metal layers, not all of the source metal 2 conductors 906 are yet fully interconnected. Similarly, all of the drain metal 2 conductors 908 are not yet fully interconnected. The FET die 102 may be embedded in a substrate and BEOL metal layers may be fabricated both inside and outside the FET die. This is in contrast to a fully functional FET die 102 in which FEOL processes result in all metal interconnects being disposed within the FET die area 102. Moreover, the BEOL metal can exist both inside and outside of the die area. This makes it possible to break the die into pieces and instead of embedding 1 large die, 2 smaller die having an area that is about equal to the one large die may be embedded. In general the smaller die will have a higher yield, consequently, the overall cost may be reduced.

FIG. 18B illustrates regions of the FET die area 102. These regions include a VDC region, a PGND region, and a SW region. These regions are described in more detail elsewhere herein. FIGS. 18A and 18B also illustrate an exemplary chiplet 118. These may also be described as unit cell building blocks. The die 102 may be comprised of an array of multiple chiplets 118 arrayed in rows and columns. For example, 2 columns of 12 rows of chiplets 118 may be arrayed in a lower FET of the die 102 of FIGS. 18A and 18B. And 3 columns of 3 rows of chiplets 118 may be arrayed in an upper FET of the die 102 of FIGS. 18A and 18B. In some embodiments, the chiplets within the upper FET have a different width from the chiplets in the lower FET. The chiplets could also be uniform in dimensions throughout the device, depending on the nature of the device.

The chiplet 118 includes gate fingers, source fingers, drain fingers, an active region and non-active regions, along with FEOL and BEOL connectors to provide signals and currents to the chiplet 118. In the FEOL metal layers, lateral current flow may be generally confined to the chiplet 118. For example, lateral flow through gate, drain, and source fingers is at most from about the center of the active area to the nearest non active region, or about half the width of the chiplet 118. This is a relatively short distance, and since there are many fingers in parallel, the current in each finger may be lower while the total current flow in parallel through all the fingers may be higher. Furthermore, the resistance may also be low.

However, lateral current flow that traverses multiple chiplets may be generally confined to flow within thick metal 2 which may be widened to accommodate the lateral current flow without impacting Wg/A. Moreover, the BEOL thick metal layers may be parallel to the FEOL layers and hence the lateral current flow may take place in very low resistance interconnect composed of both the FEOL and BEOL layers. Lateral current from metal 2 is then, in turn, communicated vertically to the metal 1 layer only through via interconnects 806, 807, and 808 in the via 2 layer that are disposed over the non-active area. A person having ordinary skill in the art with the disclosure before them would understand that the die may be considered to be composed of thousands of individual small FETs at the FEOL level, that may be organized into a large upper FET and a large lower FET (or multiple large FETs, eg., 3, 4, 5, 6, 7, 8 or more large FETs) using the BEOL connections.

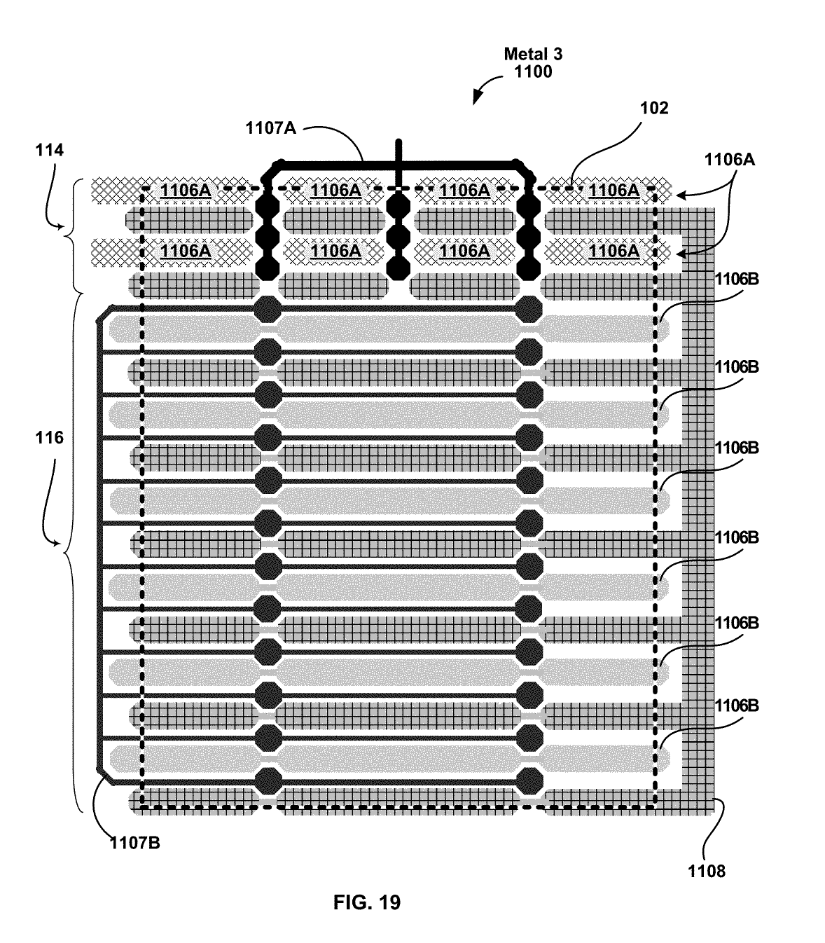

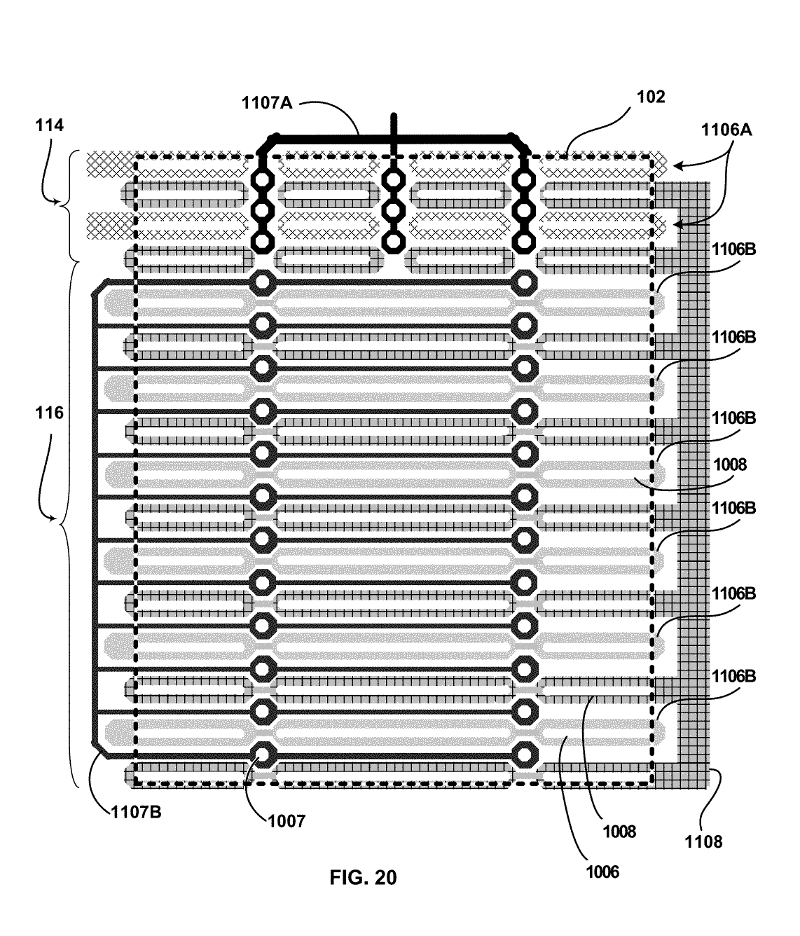

FIG. 19 illustrates a metal 3 layer 1100, in accordance with aspects of the claimed technology. FIG. 20 illustrates the metal 3 layer 1100 of FIG. 19 showing positioning of the passivation 3 openings with respect to the metal 3 features. While the passivation 3 openings of FIG. 20 are actually below the metal 3 layer 1100 and would not normally be visible, they are shown through the metal 3 features to show the relationships. FIGS. 19 and 20 include a dotted line representing an outline indicating the position of the FET die 102 in relation to the metal 3 layer 1100. It is noteworthy that the BEOL metal layers go outside of the die area. If done in FEOL then the die would be bigger to accommodate the connections. Instead the BEOL is used resulting in a smaller die, and potentially lower costs.

The FET die 102 of FIGS. 19 and 20 includes an upper FET 114 and a lower FET 116, similar to upper and lower FETs described in U.S. patent application Ser. No. 15/716,265, filed Sep. 26, 2017, entitled “Gate Driver for Depletion-Mode Transistors,” which in turn is a continuation of, and claims priority benefit of, U.S. patent application Ser. No. 15/190,095 (Now U.S. Pat. No. 9,774,322), filed Jun. 22, 2016, entitled “Gate Driver for Depletion-Mode Transistors,” which are incorporated by reference herein in their entirety including all references cited therein.

Features of the metal 3 layer 1100 include a metal 3 switch node 1108 composed of the upper FET source and lower FET drain, a metal 3 node VDC 1106A composed of the upper FETs drain, a metal 3 PGND node 1106B composed of the lower FETs source, and a metal 3 upper gate 1107A, and metal 3 lower gate 1107B. The passivation 3 openings are below the metal 3 layer 1100 and between the metal 3 layer 1100 and the metal 2 layer 130, The passivation 3 openings, thus, provide communication between the metal 3 layer 1100 and metal 2 layer 130. In general the metal 3 layer 1100 has a greater thickness than the metal 2 layer. A typical thickness for the metal 3 layer 1100 is about 12 microns. A typical thickness for the metal 2 layer 130 is about 4 microns. This is because the current in the metal 2 layer flows mostly vertically so it can be made thinner, which may serve to simplify the FEOL processing and consequently lower the cost

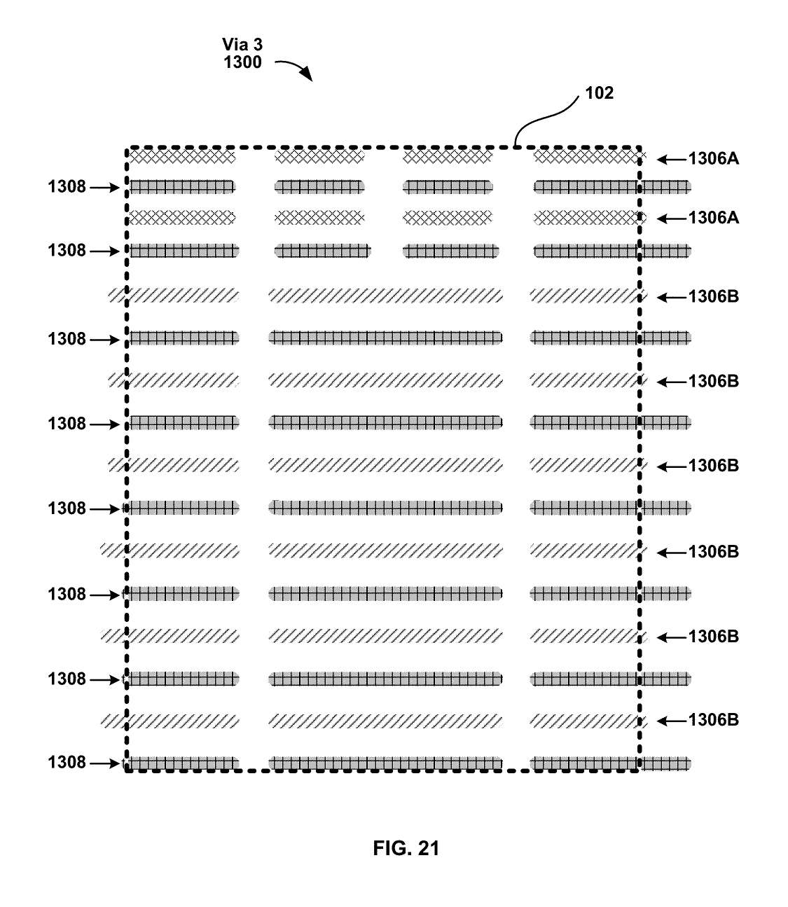

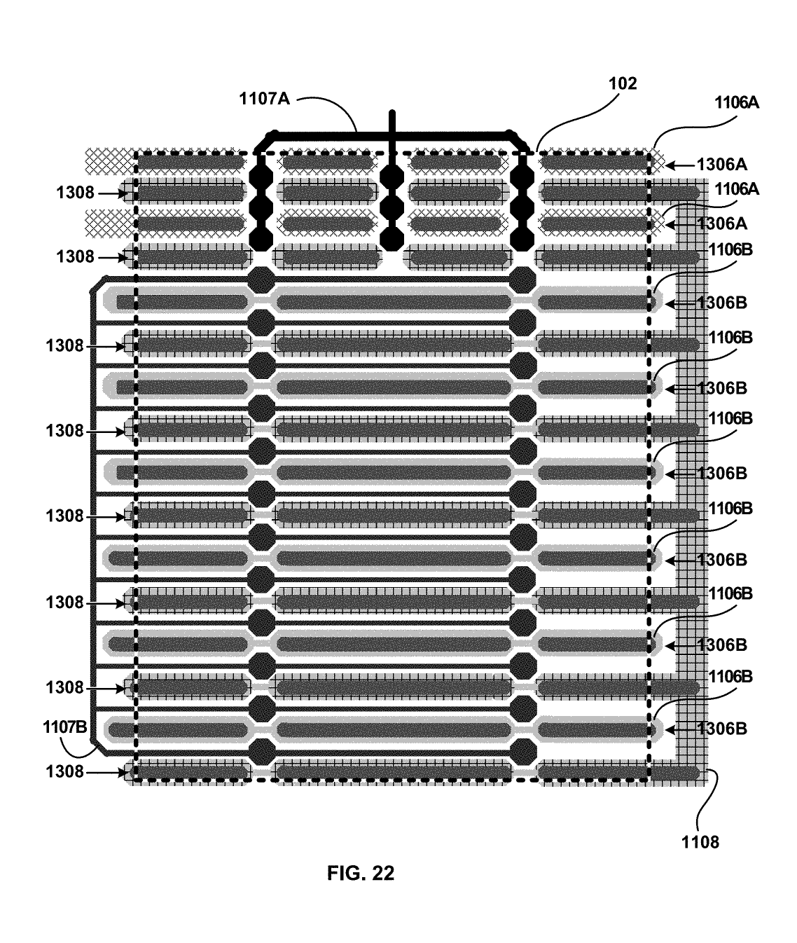

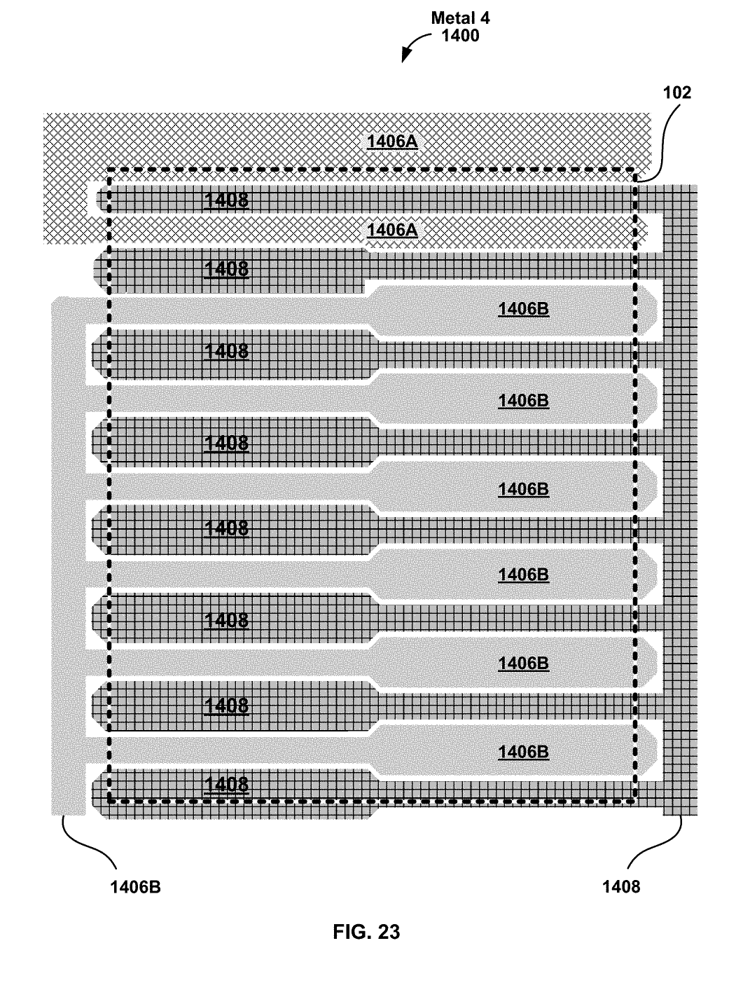

FIG. 21 illustrates a via 3 layer 1300. FIG. 22 illustrates an overlay of the via 3 layer 1300 of FIG. 21 on the metal 3 layer 1100 of FIG. 19. FIGS. 21 and 22 include a dotted line representing an outline indicating the position of the FET die 102 in relation to the metal 3 layer 1100. Features of the via 3 layer 1300 of FIGS. 21 and 22 include a via 3 VDC node 1306A for the upper FET, a via PGND node 1306B for the lower FET, and a via 3 SW node 1308. The vias in the via 3 layer 1300 provide vertical communication between the metal 3 layer 1100 illustrated in FIG. 19 and a metal 4 layer 1400 illustrated in FIG. 23, as well as lateral connectivity. For example, the FET fingers on the left side of the die may connect to the metal 5 pad on the right side of the die and visa versa. Without the via bars there would be 12 and 18 um thick Cu in parallel to effectively provide 30 um of Cu. If via 3 were a traditional via then there would be a collection of vias in parallel, and the effective metal thickness would be somewhere between 30 and little less than 42.5 um, since the width/space of the vias is generally equal. With the via bar being substantially equivalent to the under and overlying metal in dimension, the via bar serves not only to provide a vertical connection between those two layers but also a 25 um thick lateral connection in parallel with those two metal layers effectively resulting in an effective metal thickness of 55 um. Note that functionally, feature 1308 is the source of the upper FET and drain of the lower FET while feature 1306A is the drain of the upper FET and feature 1306B is the source of the lower FET.

FIG. 23 illustrates a metal 4 layer 1400. Metal 4 features of the metal 4 layer 1400 includes a metal 4 VDC node 1406A, a metal 4 PGND node 1406B, and a metal 4 SW node 1408. The metal 4 layer 1400 is an extension of the metal 3 layer 1100 to increase thickness and substantially lower resistance of currents laterally through the metal layers at a small cost of a slight increase in vertical resistance. The metal 4 layer 1400 also serves to extend interconnects beyond the FET die 102. As discussed elsewhere herein, FET fingers on the left side of the die may connect to the metal 5 pad on the right side of the die and visa versa. The distance traveled laterally can be as much as a several millimeters. Reducing lateral resistance over millimeters provides an advantageous tradeoff for increased vertical resistance of a few microns.

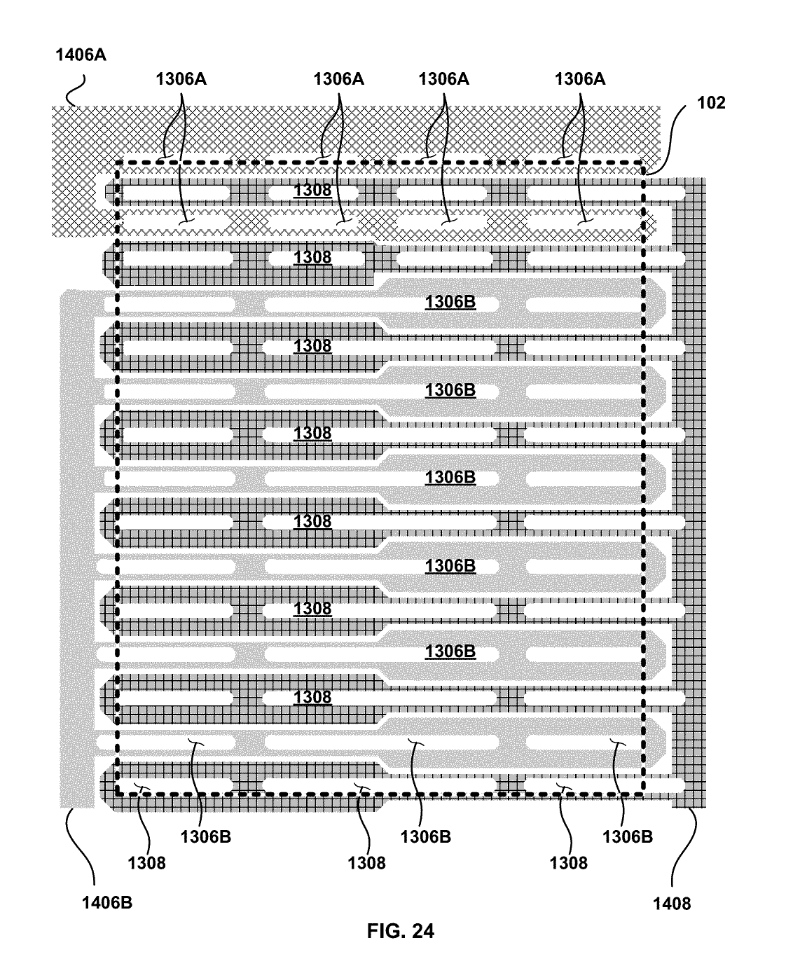

FIG. 24 illustrates the metal 4 layer 1400 of FIG. 23 showing positioning of the via 3 layer 1300 with respect to the metal 4 features. While the vias of the via 3 layer 1300 of FIG. 21 are actually below the metal 4 layer 1400 and would not normally be visible. However, they are shown through the metal 4 features in FIG. 24 to show the relationships between the via 3 features and metal 4 features. FIGS. 23 and 24 include a dotted line representing an outline indicating the position of the FET die 102 in relation to the metal 4 layer 1400.

The vias of the via 3 layer 1300, which are below the metal 4 layer 1400, are also between the metal 3 layer 1100 and the metal 4 layer 1400. The vias of the via 3 layer 1300, thus, provide vertical communication between the metal 3 layer 1100 illustrated in FIG. 19 and metal the 4 layer 1400 illustrated in FIG. 23. In general the metal 4 layer 1400 has a greater thickness than the metal 3 layer 1100. A typical thickness for the metal 4 layer 1400 is about 18 microns. A typical thickness for the metal 3 layer 1100 is about 12 microns. The vias of the via 3 layer 1300 serve as an extension of the metal 3 layer 1100 to connect metal 3 and metal 4 features. A typical thickness of the via 3 layer is about 25 um, which serves increase thickness and lower resistance and serve as an interconnect trace between the metal 3 features and metal 4 features.

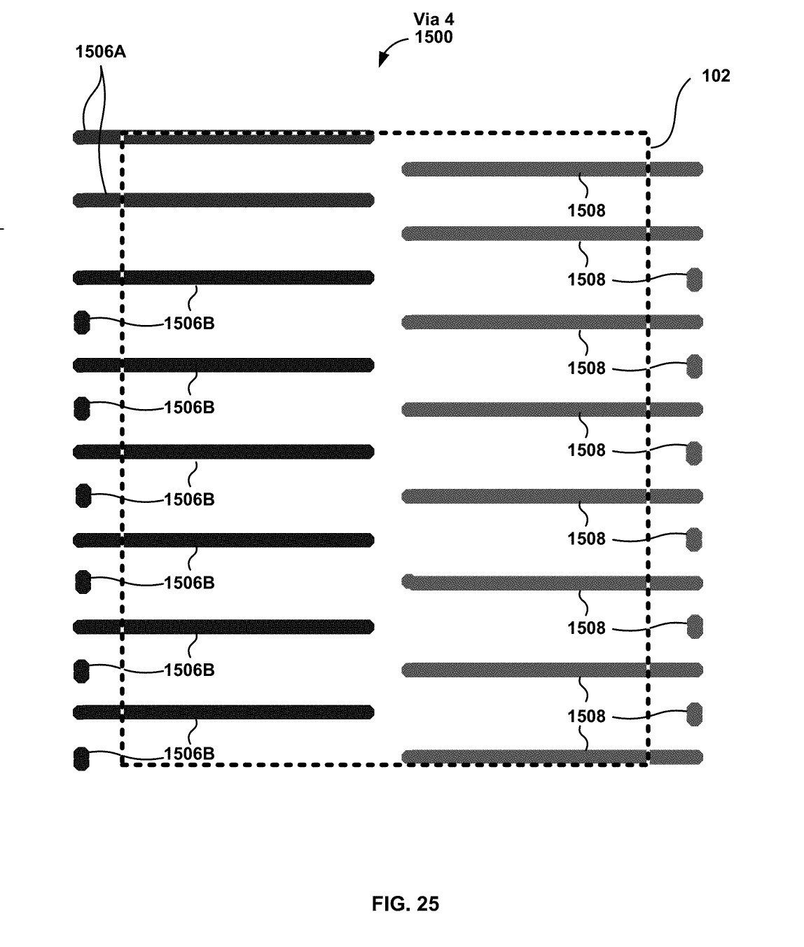

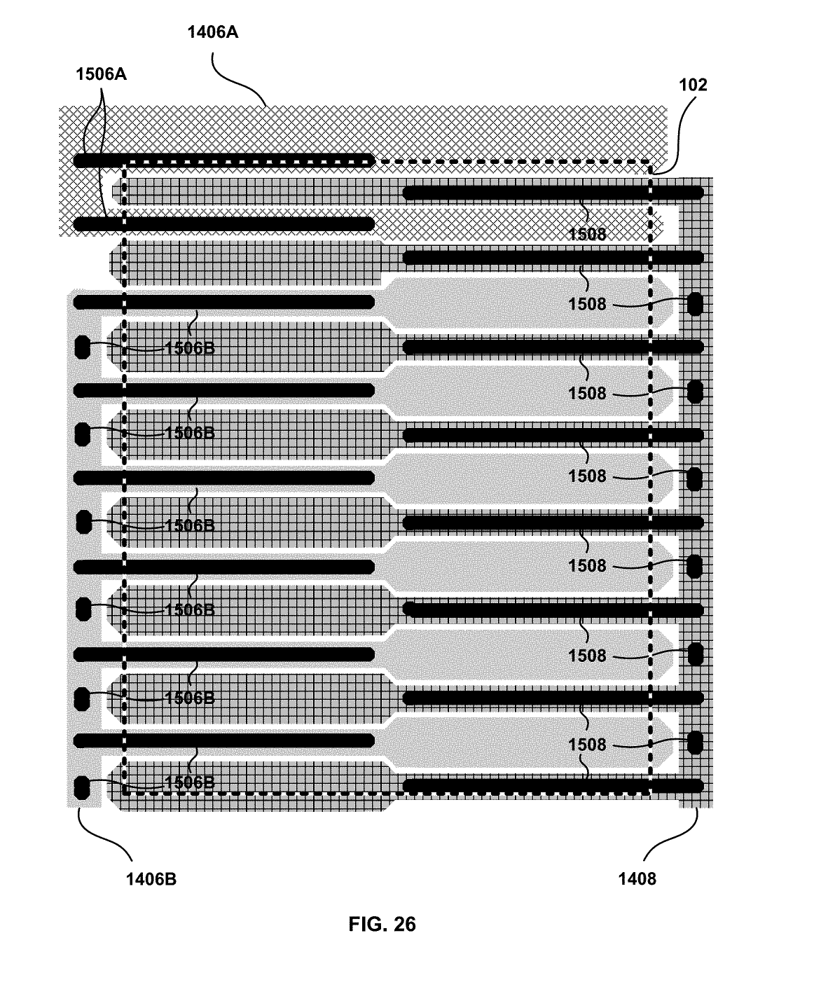

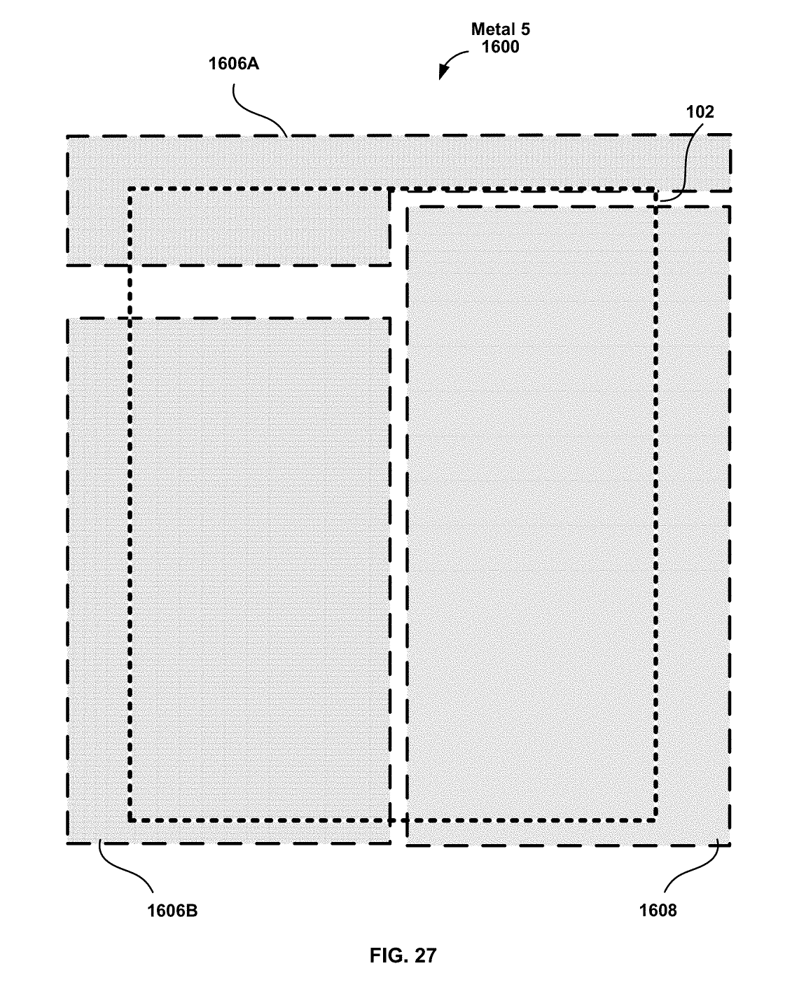

FIG. 25 illustrates a via 4 layer 1500. FIG. 26 illustrates an overlay of the via 4 layer 1500 of FIG. 25 on the metal 4 layer 1400 of FIG. 23. FIGS. 25 and 26 include a dotted line representing an outline indicating the position of the FET die 102 in relation to the via 4 layer 1500. The vias of the via 4 layer 1500 of FIGS. 25 and 26 include a via 4 VDC node 1506A for the upper FET, a via PGND node 1506B for the lower FET, and a via 4 SW node 1508. The vias in the via 4 layer 1500 provide vertical communication between the metal 4 layer 1400 illustrated in FIG. 23 and a metal 5 layer 1600 illustrated in FIG. 27. Functionally, feature 1506A are the drains of the upper FET, feature 1506B is the source of the lower FET, and feature 1508 is the source of the upper FET and drain of the lower FET.

FIG. 27 illustrates a metal 5 layer 1600. Metal 5 features of the metal 5 layer 1600 includes a metal 5 VDC node 1606A, a metal 5 PGND node 1606B, and a metal 5 SW node 1608. The metal 5 layer serves as an extension of the metal 4 layer 1400 to increase thickness and lower lateral resistance of currents upward through the metal layers. The metal 5 layer 1600 also serves to extend interconnects beyond the FET die 102 and interconnects gates.

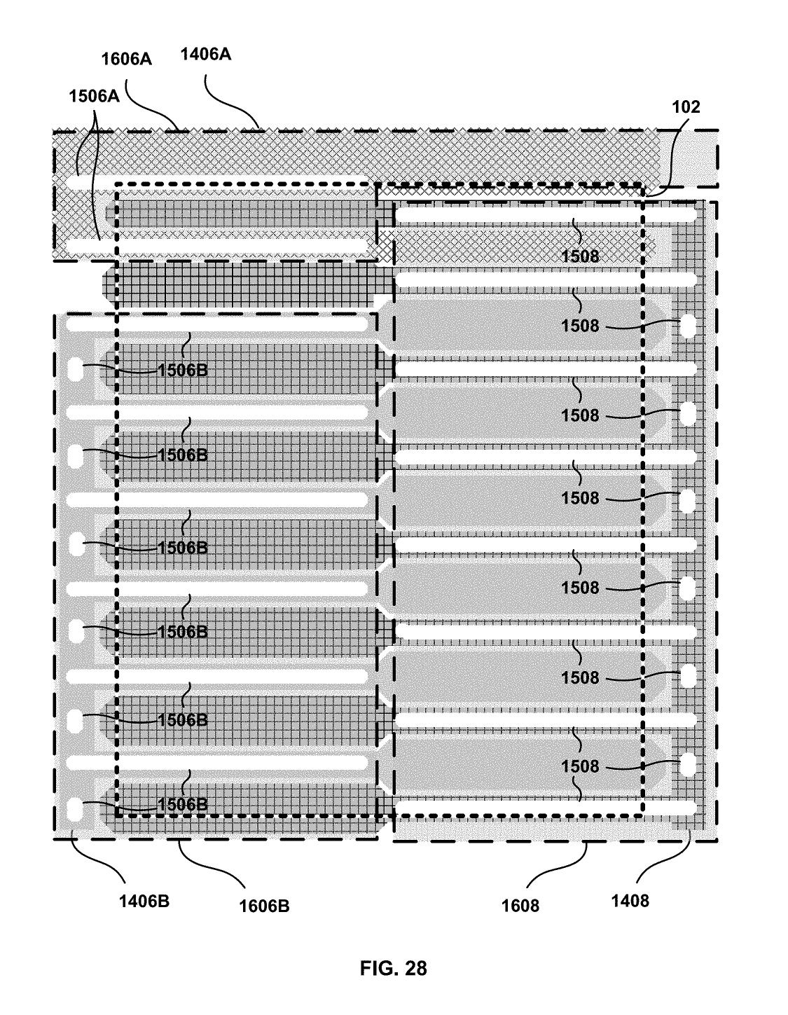

FIG. 28 illustrates the metal 5 layer 1600 of FIG. 27 showing positioning of the vias of the via 4 layer 1500 with respect to the metal 4 features and metal 5 features. The metal 4 layer 1400 and vias of the via 4 layer 1500 of FIG. 26 are actually below the metal 5 layer 1600 and would not normally be visible. However, they are shown through the metal 5 features in FIG. 28 to show the relationships between the metal 4 features, via 4 features and metal 5 features. The metal 5 features are shown in dotted lines to illustrate the relationships between the metal 4 features, via 4 features and metal 5 features. FIGS. 27 and 28 include a dotted line representing an outline indicating the position of the FET die 102 in relation to the metal 4 layer 1400.

The vias of the via 4 layer 1500, which are below the metal 5 layer 1600, are also between the metal 4 layer 1500 and the metal 5 layer 1600. The vias of the via 4 layer 1500, thus, provide vertical communication between the metal 4 layer 1400 illustrated in FIG. 23 and metal the 5 layer 1600 illustrated in FIG. 27. In general the metal 5 layer 1600 has a greater thickness than the metal 4 layer 1400. A typical thickness for the metal 5 layer 1600 is about 40 microns. A typical thickness for the metal 4 layer 1400 is about 18 microns. The vias of the via 4 layer 1500 serve as an extension of the metal 4 layer 1400 to connect metal 4 and metal 5 features. A typical thickness of the via 4 layer is about 25 microns, which serves to increase thickness and lower lateral resistance and serve as an interconnect trace between the metal 4 features and metal 5 features. In some embodiments, the metal 4 layer is thicker—40 um—because it is used as an interconnect and not a pad as shown in these figures and elsewhere. There may be a corresponding metal layer on the topside which balances the metal and may advantageously be the same thickness. In embodiments where outer layers are not used for routing the outer layers may be 20 um.

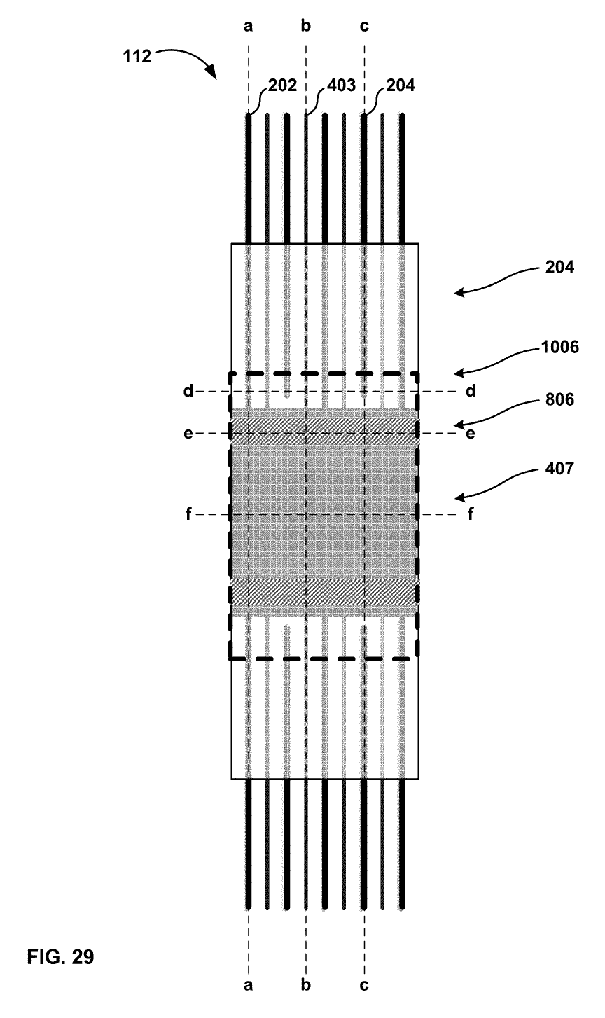

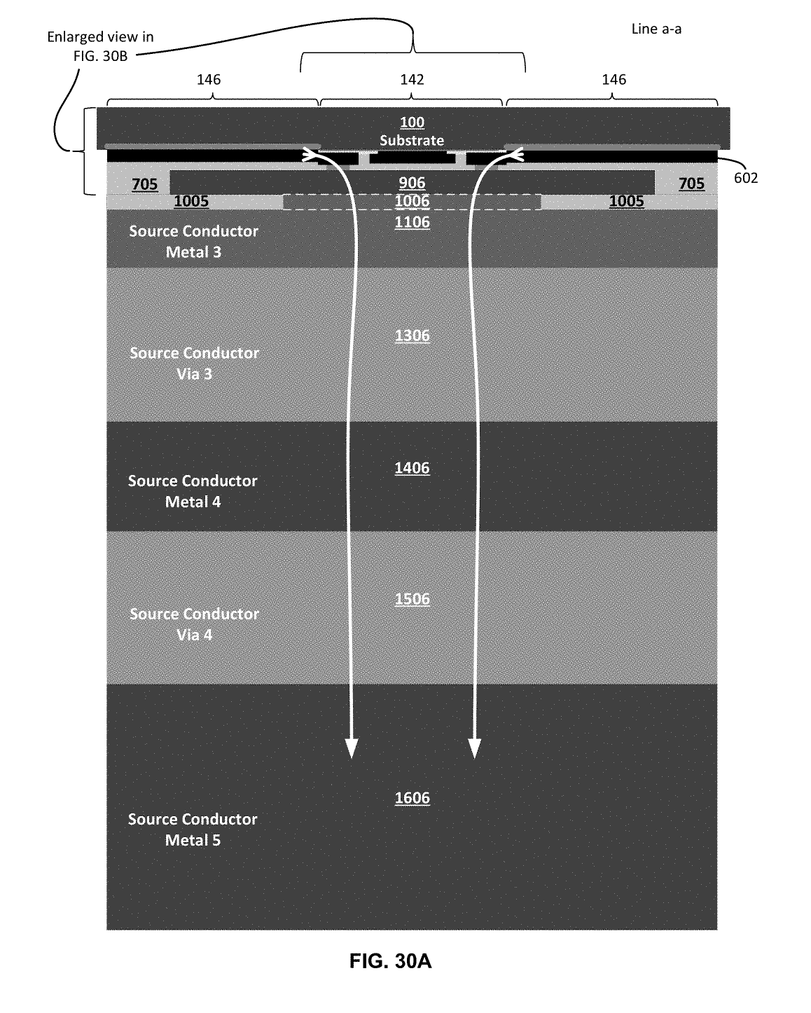

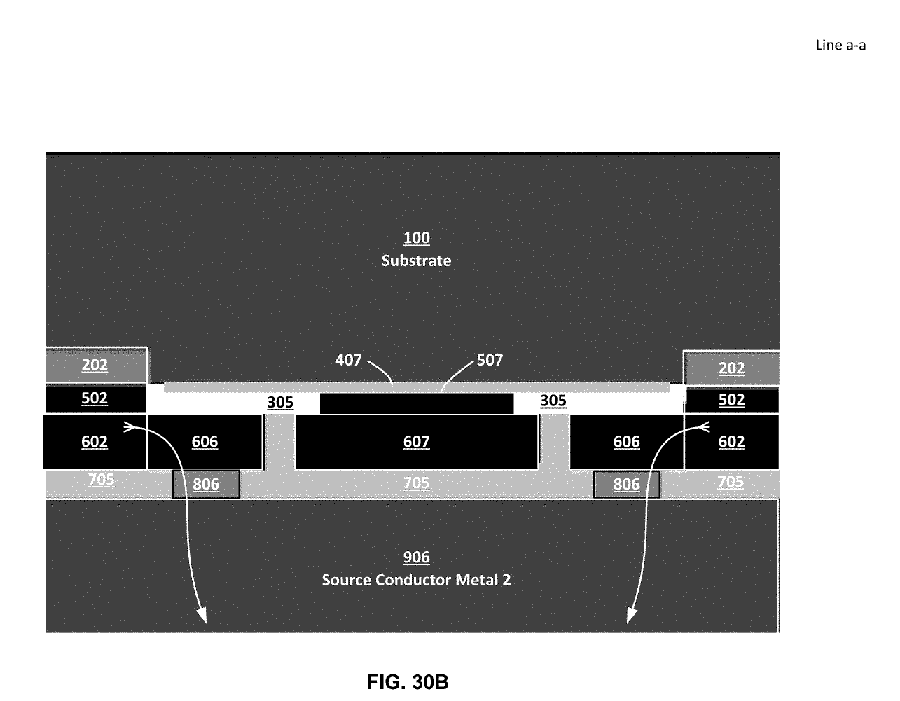

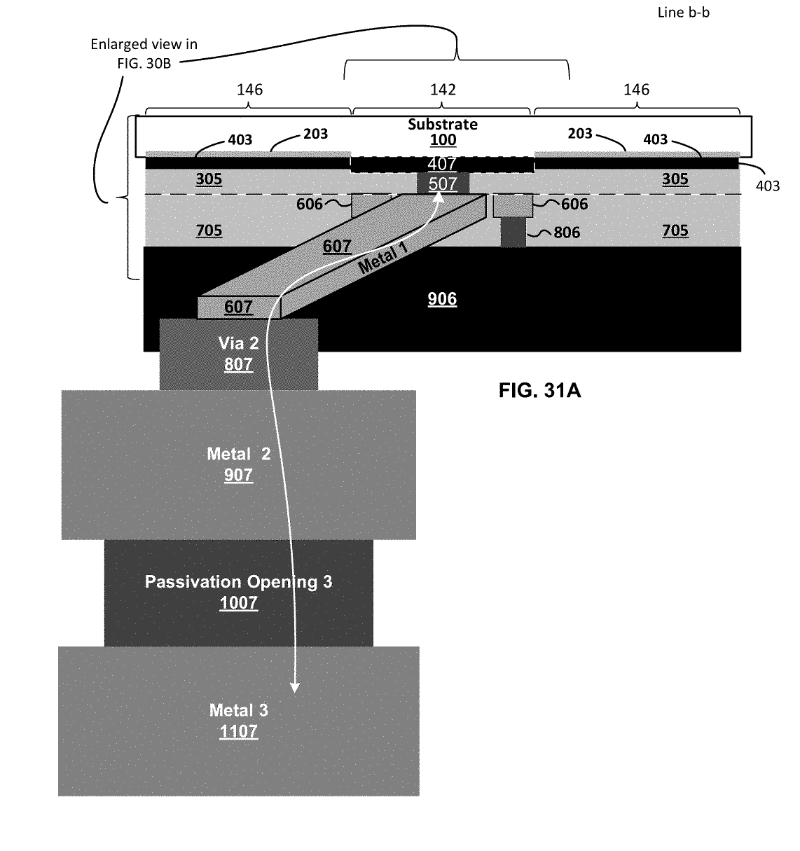

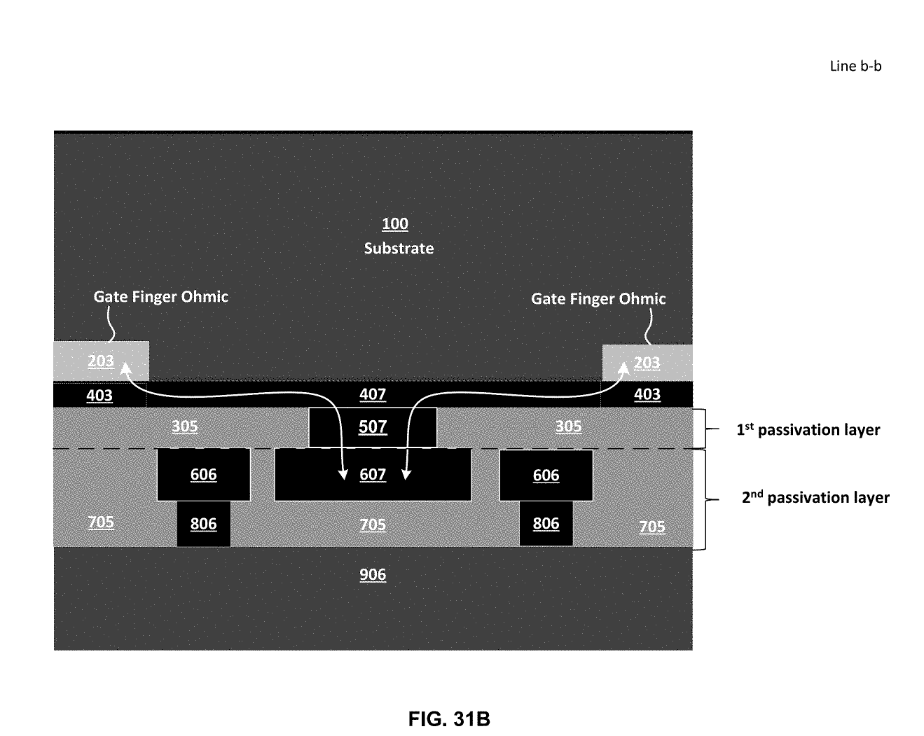

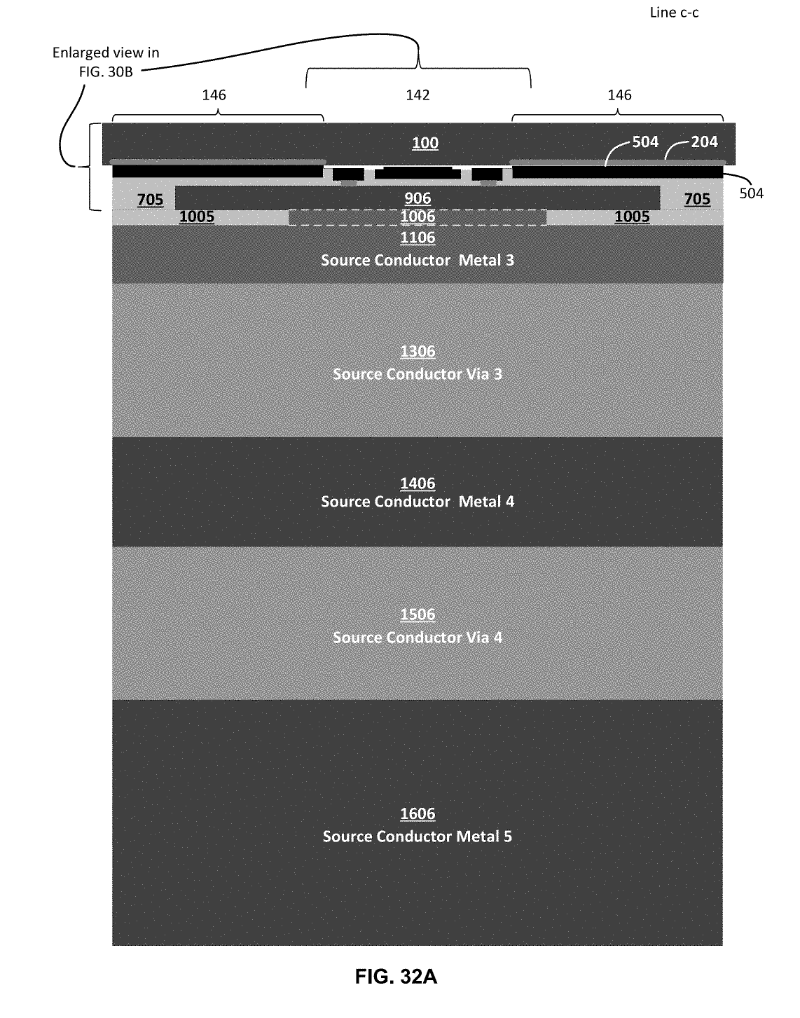

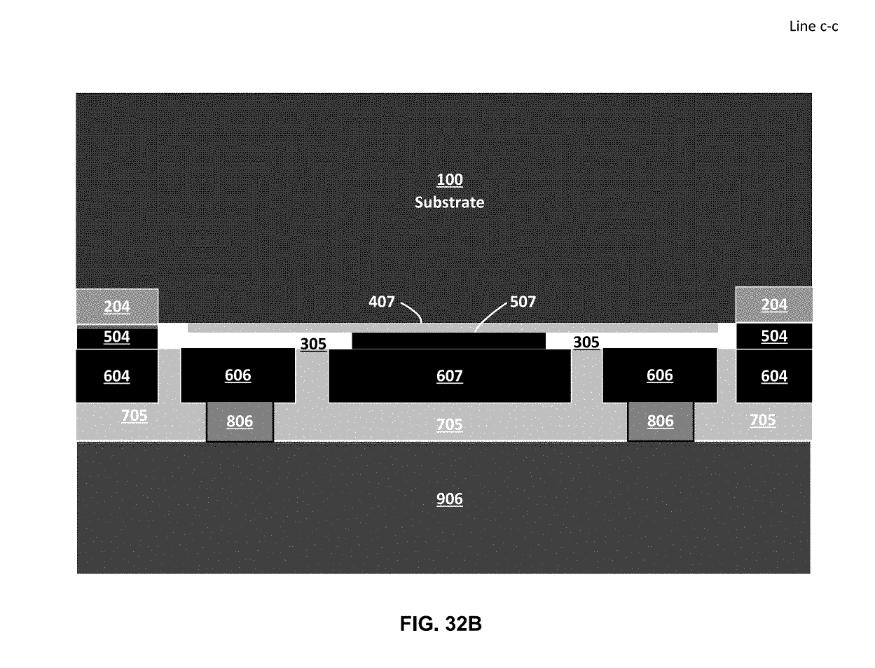

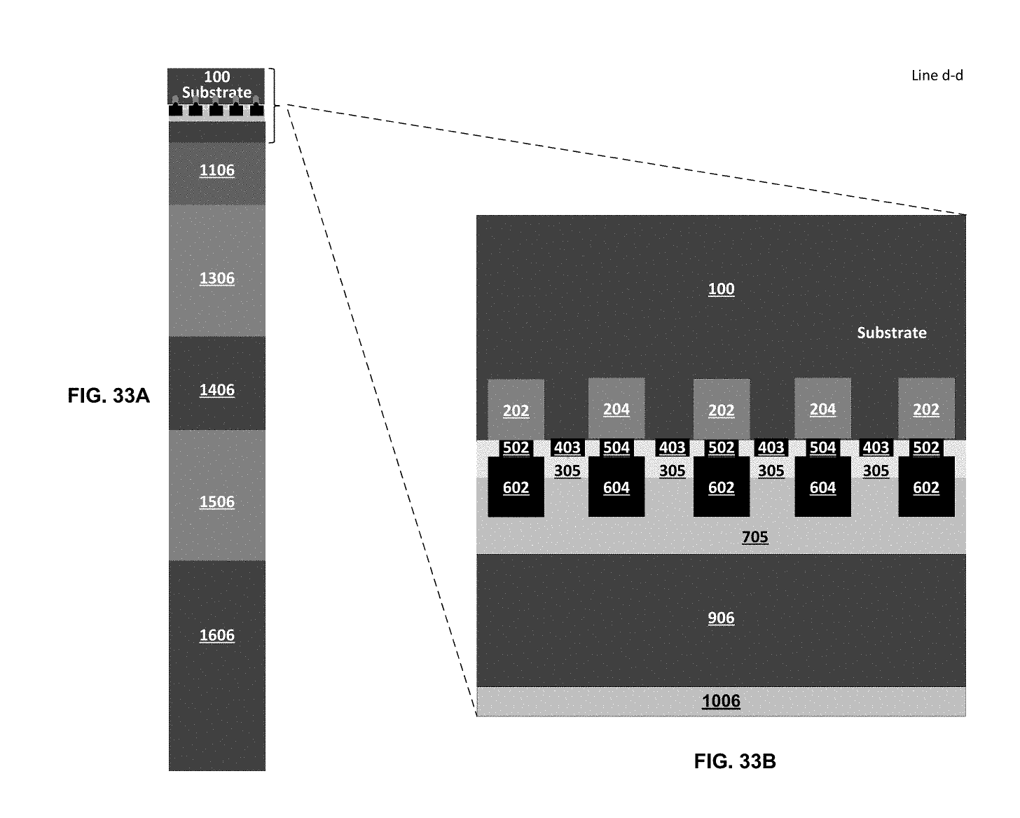

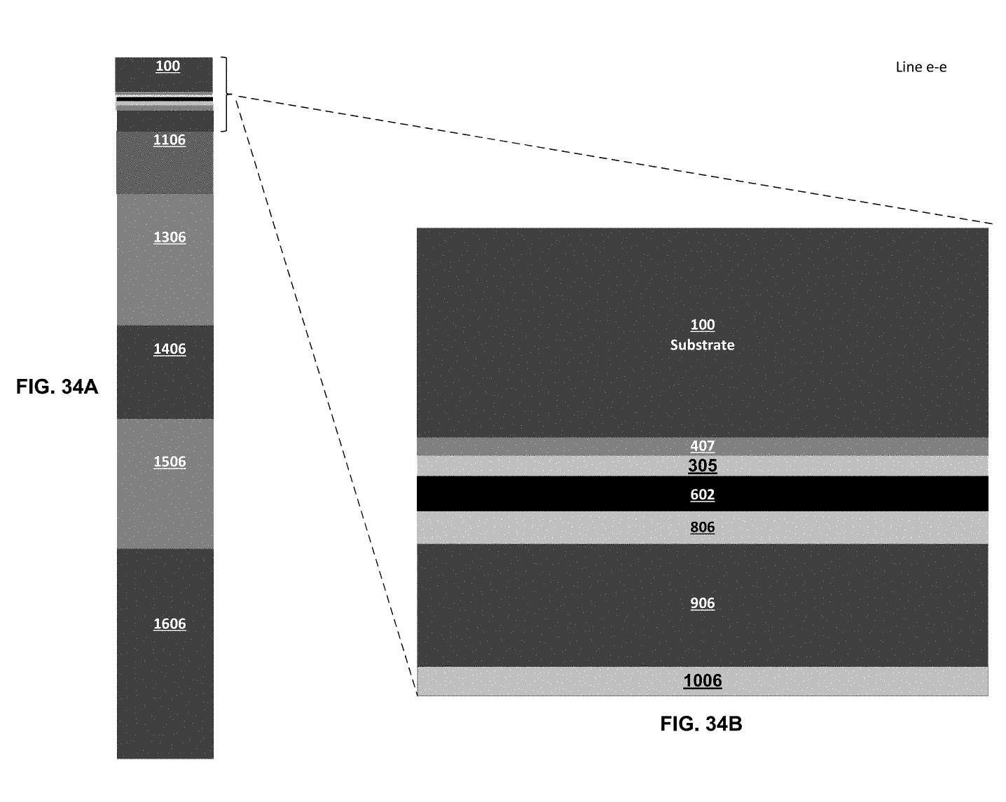

FIG. 29 is a portion of FIG. 16B for showing cross section positions. Line a-a indicates a cross section along the length of source fingers, further illustrated and describe with respect to FIG. 30. Line b-b indicates a cross section along the length of gate fingers, further illustrated and describe with respect to FIG. 31. Line c-c indicates a cross section along the length of drain fingers, further illustrated and describe with respect to FIG. 32. Line d-d indicates a cross section along a passivation 3 source opening 1006 and at right angles to source, gate, and drain fingers, further illustrated and describe with respect to FIG. 33. Line e-e indicates a cross section along a source via 2 interconnect 806, further illustrated and describe with respect to FIG. 33. Line f-f indicates a cross section along a gate metal conductor 407, further illustrated and describe with respect to FIG. 34.

FIG. 30A illustrates a cross section along the length of source fingers. FIG. 30B is an enlargement of a portion of the cross section of FIG. 30A. FIGS. 30A and 30B are inverted with respect to the progression of the views of FIGS. 3-29. That is, the substrate of the die 102 and the ohmic metal layer 120 illustrated in FIG. 3 (including ohmic source metal fingers 202) is at the top of FIGS. 30A and 30B. The metal 5 layer illustrated in FIG. 27 is at the bottom of FIG. 30A.

Current from the source fingers 202 may be conducted laterally through the metal deposited in the source finger via 502 and the metal 1 finger 602 to the source metal 1 conductor 606. The source via 2 interconnect 806 conducts current (arrows) vertically from the source metal 1 conductor 606 to the source metal 2 conductor 906, where the source current is conducted vertically through the source conductor passivation 3 opening 1006 to the source metal 3 conductor 1106A/B, then through the source via 3 conductor 1306A/B to the source metal 4 conductor 1406A/B, which is connected through the source via 4 conductor 1506A/B to the source metal 5 conductor 1606A/B. A first passivation layer 305 is also illustrated, and is disposed between the substrate of the die 102 and a second passivation layer 705. The second passivation layer 705 is disposed between the first passivation layer 305 and a third passivation layer 1005. The first, second, and third passivation layers are described in more detail elsewhere herein.

FIG. 31A illustrates a cross section along the length of gate fingers. FIG. 31B is an enlargement of a portion of the cross section of FIG. 31A. FIGS. 31A and 31B are inverted with respect to the progression of the views of FIG. 3-FIG. 29. That is, the ohmic metal layer 120 illustrated in FIG. 3 is at the top of FIGS. 31A and 31B. The metal 5 layer illustrated in FIG. 27 is at the bottom of FIG. 31A.

Current (arrows) to or from the gate fingers 403 may be conducted laterally through the gate metal fingers 403 (disposed between the source fingers 202 and drain fingers 204) to the gate metal 407. The gate current is then conducted vertically through gate metal 407, through the gate conductor metal in the gate via 507 of the via 1 layer 124, and through the gate metal 1 conductor 607. The gate conductor 607 conducts gate current laterally to the gate via 807. For example, see FIG. 12A in which the arrows show an example of one of multiple lateral paths of gate current from the region 112 through the gate metal 1 conductor 607 to gate vias 807.

The gate via 807 in the via 2 layer 128 conducts gate current vertically from the gate metal 1 conductor 607 to the gate metal 2 conductor 907, which conducts the gate current through the passivation 3 gate vias 1007 to the gate metal 3 conductor 1107. Note, the gate via 807, gate metal 2 conductors 907, passivation 3 gate vias 1007, and gate metal 3 conductor 1107 of FIG. 31A are not illustrated in FIG. 31B.

FIG. 32A illustrates a cross section along the length of drain fingers. FIG. 32B is an enlargement of a portion of the cross section of FIG. 32A. FIGS. 32A and 32B are inverted with respect to the progression of the views of FIGS. 3-29. That is, the ohmic metal layer 120 illustrated in FIG. 3 is at the top of FIGS. 32A and 32B. The metal 5 layer illustrated in FIG. 27 is at the bottom of FIG. 32A.

Current from the drain ohmic fingers 204 may be conducted progressively through the metal deposited in the drain via 1 finger 504 to the drain metal 1 finger 604. Note that the drain metal 1 finger 604 ends without contacting the source metal 1 conductor 606. Instead, the opposite end of the drain metal 1 finger 604 is in contact with the drain metal 1 conductor 608. Thus, drain current is conducted laterally through the drain via 1 finger 504 and drain metal 1 finger 604 to the drain metal 1 conductor 608.

The drain via 1 conductor 808 then conducts drain current vertically from the drain metal 1 conductor 608 to the drain metal 2 conductor 908, which in turn conducts the drain current vertically through the drain conductor passivation 3 opening 1008 to the drain metal 3 conductor 1108, which is connected through the drain via 3 conductor 1308 to the drain metal 4 conductor 1408, which is connected through the drain via 4 conductor 1508 to the drain metal 5 conductor 1608 in a manner analogous to illustrations in FIG. 30A and FIG. 30B for source current.

However, drain metal 1 conductor 608, drain via 1 conductor 808, drain metal 2 conductor 908, drain conductor passivation 3 opening 1008, drain metal 3 conductor 1108, drain via 3 conductor 1308, drain metal 4 conductor 1408, drain via 4 conductor 1508, and the drain metal 5 conductor 1608 are not illustrated in the cross section figures.

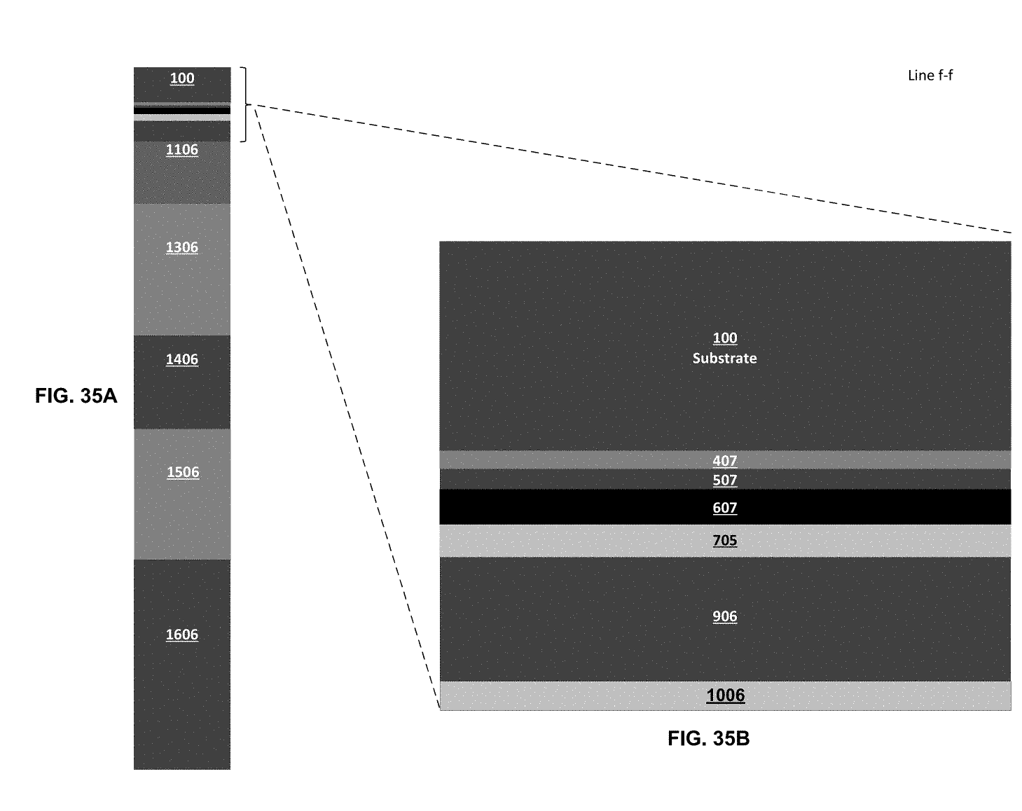

FIG. 33A illustrates a cross section taken along line d-d of FIG. 29. FIG. 33B is an enlargement of a portion of the cross section of FIG. 33A. FIG. 34A illustrates a cross section taken along line e-e of FIG. 29. FIG. 34B is an enlargement of a portion of the cross section of FIG. 34A. FIG. 35A illustrates a cross section taken along line f-f of FIG. 29. FIG. 35B is an enlargement of a portion of the cross section of FIG. 34A.

It is important to note that as the current travels from the fingers to the metal 5 layer, the metal thickness and cross section area increases at each level. Effectively this results in a progressively increasing cross section area in the direction of the current conduction at each layer. This increase in thickness cross section area of the metal at each layer progressively reduces the resistance and/or impedance for conducting the current and heat.

For example, the source current may be conducted laterally along the source fingers through metal in the source via 1 and source metal 1 fingers to the source metal 1 conductor 606. These features may be relatively thin, typically 2 microns. However, there may be many fingers in the active area, so each finger can be conducting relatively small currents that in parallel cumulatively constitute a relatively large current. In the process, the source current (and similarly the drain and gate currents) is conducted out of the active area that is entirely composed of ohmic fingers to the non-active area composed of connecting elements where the currents can be gathered and moved vertically out of the device.

Upon reaching the source metal 1 conductor (and similarly drain and gate metal 1 conductors), the current conduction becomes more vertical through the via 2 features to the source metal 2 conductor. The via 2 features present cross section areas in the direction of conduction that are substantially lager than the metal 1 and via 1 fingers. The via 2 features can have substantially larger cross section areas because they are disposed in the non-active region of the device.

The metal 2 conductor features are also disposed above the non-active region of the device. However, the metal 2 conductor features are also isolated from the active region and makes no direct contact with the active area. Thus, the widths of metal 2 conductor features are not constrained by dimensions of the non-active region. This allows the cross section area of features in the metal 2 conductor layer to be substantially larger than the cross section area of features in the metal 1 conductor layer and larger than the cross section area of the via 2 features. This is illustrated in FIG. 13A/B and FIG. 14A/B, particularly in comparison to FIG. 9A/B and FIG. 11A/B.

As discussed elsewhere herein, the metal 2 features primarily serve to provide vertical connection from the metal 1 features to the metal 3 features. For example, a typical thickness for the source metal 2 conductor 906 is about 4 microns. However, that is along the vertical direction of conduction. Since the cross section area of the source metal 2 conductor 906 is substantially larger than the cross section area of the source metal 1 conductor 606 (see, e.g., FIG. 3) resistance and/or impedance is substantially reduced.

The metal 3 features are even thicker and have even larger cross section areas than the respective metal 2 features to which they are connected. For example, the source metal 3 conductors 1106A/B illustrated in FIG. 19 has a substantially larger cross section area than the source metal 2 conductors 906 illustrated in FIG. 13A/B. Likewise, metal 4 features may be thicker and have larger cross section areas than metal 3 features, and metal 5 features may be even thicker and have even larger cross section areas than metal 4 features.

In some embodiments, a thickness for metal 3 features is about 12 microns, for metal 4 features about 18 microns, and for metal 5 about 40 microns. However, these are only exemplary dimensions; other dimensions are contemplated. The metal 3 features (metal 3 layer 1100 shown in FIG. 19), metal 4 features (metal 4 layer 1400 shown in FIG. 23), and metal 5 features (metal 5 layer 1600 shown in FIG. 27) have cross section areas for features in each successive layer that are also progressively larger, thus, further reducing resistance/impedance and costs to fabricate.

While the described structures illustrate an example of 2 metal FEOL layers on the GaAs die and 3 metal layers in the BEOL layers, other configurations and/or materials (e.g., Si) are contemplated. Persons having ordinary skill in the art with this disclosure before them would understand that there could be 3 metal FEOL layers and 6 metal BEOL layers. The number of layers in FEOL and BEOL depends on the application and desired results.

The larger features of the metal 3-5 layers and via 3-4 may be fabricated using Back End of Line (BEOL) technology, which is less expensive than Front End of Line (FEOL) technology. Optionally, the metal 2 layer and passivation 3 openings may be fabricated using either FEOL or BEOL technology. The FEOL and BEOL technology may be integrated by fabricating BEOL features directly on a die that has been fabricated using FEOL technology.

The above description is illustrative and not restrictive. This patent describes in detail various embodiments and implementations of the present invention and the present invention is open to additional embodiments and implementations, further modifications, and alternative constructions. There is no intention in this patent to limit the invention to the particular embodiments and implementations disclosed; on the contrary, this patent is intended to cover all modifications, equivalents and alternative embodiments and implementations that fall within the scope of the claims. Moreover, embodiments illustrated in the figures may be used in various combinations. Any limitations of the invention should, therefore, be determined not with reference to the above description, but instead should be determined with reference to the appended claims along with their full scope of equivalents.

What is claimed is:

1. A gallium arsenide device comprising:
a front end of line portion fabricated on a gallium arsenide substrate, the front end of line portion including:
an active region comprising:
a plurality of drain ohmic fingers and plurality of source ohmic fingers alternating with the drain fingers,
gate fingers disposed between the drain fingers and the source fingers,
a gate metal layer including the gate fingers disposed on the substrate,
a first passivation layer disposed over the substrate and gate metal layer, the first passivation layer including source vias disposed over the plurality of source ohmic fingers and drain vias disposed over the plurality drain ohmic fingers, and
a metal 1 layer including:
source metal 1 fingers disposed on the plurality of source ohmic fingers and within the plurality of source vias, and
drain metal 1 fingers disposed on the plurality of drain ohmic fingers and within the drain vias; and
a non-active region disposed between active regions of the substrate, the non-active region comprising:
a length of gate metal conductor disposed on the substrate and contiguous laterally with the gate fingers,
a gate interconnect via about the length of the gate metal conductor disposed in the first passivation layer, on a portion of the gate metal conductor,
the metal 1 layer further comprising:
a metal 1 gate conductor at least the length of the gate metal conductor and disposed on a portion of width of the gate metal conductor including the gate interconnect via, the gate interconnect via providing electrical interconnection between the gate metal 1 conductor and the gate metal conductor, and
a source metal 1 conductor about the length of the gate metal conductor and disposed on the first passivation layer contiguous laterally with the plurality of source fingers, and
a second passivation layer disposed over the active and non-active regions, including the metal 1 layer, the second passivation layer including a second source interconnect via about the length of the gate metal conductor and disposed over a portion of the width the source metal 1 conductor, the second passivation layer not including vias for providing interconnection to source fingers in the active region.

2. The gallium arsenide device of claim 1, further comprising a nitride layer between the gate metal and the substrate.

3. The gallium arsenide device of claim 1, wherein the non-active region further comprises a source metal 2 conductor at least the length of the gate metal conductor and disposed on the second passivation layer, and on the metal 1 conductors within the second source interconnect via, the second source interconnect via providing vertical interconnection through the second passivation layer between the source metal 2 conductor and the source metal 1 conductor.

4. The gallium arsenide device of claim 1, further comprising:
a back end of line portion fabricated directly on the front end of line portion, the back end of line portion comprising:
a source metal 3 conductor disposed on the third FEOL passivation layer and in electrical communication vertically through the source passivation opening in the third FEOL passivation layer to the source metal 2 conductor,
a fourth PCB material layer including a third interconnect via;
a source metal 4 conductor disposed on the forth PCB layer and in electrical communication vertically through the third interconnect via in the forth PCB layer to the source metal 3 conductor;
a fifth PCB material layer including a forth interconnect via;
a source metal 5 conductor disposed on the fifth PCB layer and in electrical communication vertically through the forth interconnect via in the fifth PCB layer to the source metal 3 conductor.

5. The gallium arsenide device of claim 1, further comprising:
a back end of line portion fabricated on the front end of line portion, the back end of line portion comprising:
a source metal 2 conductor at least the length of the metal 1 conductors and disposed on the second passivation layer, and on the metal 1 conductors within the second source interconnect via, the second source interconnect via providing vertical interconnection through the second passivation layer between the source metal 2 conductor and the source metal 1 conductor;
a third passivation layer including a source passivation opening;
a source metal 3 conductor disposed on the third passivation layer and in electrical communication vertically through the source passivation opening in the third passivation layer to the source metal 2 conductor,
a fourth passivation layer including a third interconnect via;
a source metal 4 conductor disposed on the forth passivation layer and in electrical communication vertically through the third interconnect via in the forth passivation layer to the source metal 3 conductor;
a fifth passivation layer including a forth interconnect via; and
a source metal 5 conductor disposed on the fifth passivation layer and in electrical communication vertically through the forth interconnect via in the fifth passivation layer to the source metal 3 conductor.

6. The gallium arsenide device of claim 1, wherein the metal 1 layer further comprises a drain metal 1 conductor about the length of the gate metal conductor and disposed on the first passivation layer contiguous laterally with the plurality of drain fingers,

7. The gallium arsenide device of claim 6, wherein the non-active region further comprises: a drain metal 2 conductor at least the length of the gate metal conductor and disposed on the second passivation layer, and on the metal 1 conductors within the second drain interconnect via, the second drain interconnect via providing vertical interconnection through the second passivation layer between the drain metal 2 conductor and the drain metal 1 conductor.

8. The gallium arsenide device of claim 7, further comprising:
a back end of line portion fabricated on the front end of line portion, the back end of line portion comprising:
a third passivation layer including a drain passivation opening;
a drain metal 3 conductor disposed on the third passivation layer and in electrical communication vertically through the drain passivation opening in the third passivation layer to the drain metal 2 conductor,
a fourth passivation layer including a third interconnect via;
a drain metal 4 conductor disposed on the forth passivation layer and in electrical communication vertically through the third interconnect via in the forth passivation layer to the drain metal 3 conductor;
a fifth passivation layer including a forth interconnect via;
a drain metal 5 conductor disposed on the fifth passivation layer and in electrical communication vertically through the forth interconnect via in the fifth passivation layer to the drain metal 3 conductor.

9. A gallium arsenide device comprising:
a gallium arsenide substrate comprising:
alternating drain ohmic fingers and source ohmic fingers disposed within the substrate, and
gate fingers disposed between the drain fingers and the source fingers, the source ohmic fingers, drain ohmic fingers, and gate fingers form an active region of the gallium arsenide device,
a gate metal layer comprising:
a gate metal conductor disposed on a non-active region between adjacent active regions, and
gate metal fingers disposed on the gate fingers in the active region, the gate metal fingers in direct electrical contact with the gate metal conductor;
a first passivation layer disposed on the substrate and gate metal layer, the first passivation layer comprising:
source vias disposed over the source ohmic fingers,
drain vias disposed over the drain ohmic fingers, and
a gate via disposed within the non-active region over the gate metal conductor;
a metal 1 layer disposed on the first passivation layer, the metal 1 region comprising:
source metal 1 fingers disposed on the first passivation layer and in electrical communication with the source ohmic fingers through the source vias,
a source metal 1 conductor disposed on the first passivation layer within the non-active region and in direct electrical contact with the source metal 1 fingers,
drain metal 1 fingers disposed on the first passivation layer and in electrical communication with the drain ohmic fingers through the drain vias,
a drain metal 1 conductor disposed on the first passivation layer within the non-active region and in direct electrical contact with the drain metal 1 fingers, and
a gate metal 1 conductor disposed on the first passivation layer within the non-active region and in direct electrical contact with the gate metal through the gate via;
a second passivation layer disposed on the first passivation layer and the metal 1 layer, the second passivation layer comprising:
a source via 2 disposed within the non-active region and over the source metal 1 conductor,
a drain via 2 disposed within the non-active region and over the drain metal 1 conductor, and
a gate a via 2 disposed within the non-active region and over the gate metal 1 conductor.

10. The gallium arsenide device 9, further comprising a metal 2 layer disposed on the via 2 layer, the metal 2 layer comprising:
a source metal 2 conductor disposed on the second passivation layer and in electrical communication with the source metal 1 conductor through the source via 2,
a drain metal 2 conductor disposed on the second passivation layer and in electrical communication with the drain metal 1 conductor through the drain via 2, and.
a gate metal 2 conductor disposed on the second passivation layer and in electrical communication with the gate metal 1 conductor through the gate via 2.

11. The gallium arsenide device of claim 10, further comprising:
a third passivation layer disposed on the second passivation layer and the metal 2 layer, the third passivation layer comprising:
a source passivation via 3 disposed over the source metal 2 conductor,
a drain passivation via 3 disposed over the drain metal 2 conductor, and
a gate passivation via 3 disposed over gate metal conductor; and
a metal 3 layer disposed on the third passivation layer, the metal 3 layer comprising:
a source metal 3 conductor disposed on the third passivation layer and in electrical communication with the source metal 2 conductor through the source via 3,
a drain metal 3 conductor disposed on the third passivation layer and in electrical communication with the drain metal 2 conductor through the drain via 3 and
a gate metal 3 conductor disposed on the third passivation layer and in electrical communication with the gate metal 2 conductor through the gate via 3.

12. The gallium arsenide device of claim 11, further comprising:
a forth passivation layer disposed on the third passivation layer and the metal 3 layer, the forth passivation layer comprising:
a source passivation via 4 disposed over the source metal 3 conductor, and
a drain passivation via 4 disposed over the drain metal 3 conductor;
a metal 4 layer disposed on the forth passivation layer, the metal 4 layer comprising:
a source metal 4 conductor disposed on the third passivation layer and in electrical communication with the source metal 3 conductor through the source via 4, and
a drain metal 4 conductor disposed on the forth passivation layer and in electrical communication with the drain metal 3 conductor through the drain via 4.

13. The gallium arsenide device of claim 12, further comprising:
a fifth passivation layer disposed on the forth passivation layer and the metal 4 layer, the fifth passivation layer comprising:
a source passivation via 5 disposed over the source metal 4 conductor, and
a drain passivation via 5 disposed over the drain metal 4 conductor;
a metal 5 layer disposed on the fifth passivation layer, the metal 5 layer comprising:
a source metal 5 conductor disposed on the forth passivation layer and in electrical communication with the source metal 4 conductor through the source via 5, and
a drain metal 5 conductor disposed on the fifth passivation layer and in electrical communication with the drain metal 4 conductor through the drain via 5.

14. The gallium arsenide device of claim 13, wherein the gate metal layer first passivation layer, metal 1 layer, second passivation layer, and metal 2 layer are fabricated on the substrate using front end of line processes.

15. The gallium arsenide device of claim 14, wherein the third passivation layer, metal 3 layer, forth passivation layer, metal 4 layer, fifth passivation layer, and metal 5 layer are fabricated on the substrate using back end of line processes.

16. The gallium arsenide device of claim 13, wherein the gate metal layer first passivation layer, metal 1 layer, and second passivation layer are fabricated on the substrate using front end of line processes.

17. The gallium arsenide device of claim 16, wherein the metal 2 layer, third passivation layer, metal 3 layer, forth passivation layer, metal 4 layer, fifth passivation layer, and metal 5 layer are fabricated on the substrate using back end of line processes.

18. A method for fabricating a device, the method comprising:
fabricating ohmic fingers in an active region of a gallium arsenide substrate, the ohmic fingers comprising:
alternating drain ohmic fingers and source ohmic fingers disposed within the substrate, and
gate fingers disposed between the drain fingers and the source fingers;
fabricating a gate metal layer using a front end of line (FEOL) process, the gate metal layer comprising:
a gate metal conductor disposed on a non-active region between adjacent active regions of ohmic fingers, and
gate metal fingers disposed on the gate fingers in the active region, the gate metal fingers in direct electrical contact with the gate metal conductor;
fabricating a first passivation layer on the substrate and gate metal layer using FEOL, the first passivation layer comprising:
source vias disposed over the source ohmic fingers,
drain vias disposed over the drain ohmic fingers, and
a gate via disposed within the non-active region over the gate metal conductor;
fabricating a metal 1 layer on the first passivation layer using FEOL processes, the metal 1 region comprising:
source metal 1 fingers disposed on the first passivation layer and in electrical communication with the source ohmic fingers through the source vias,
a source metal 1 conductor disposed on the first passivation layer within the non-active region and in direct electrical contact with the source metal 1 fingers,
drain metal 1 fingers disposed on the first passivation layer and in electrical communication with the drain ohmic fingers through the drain vias,
a drain metal 1 conductor disposed on the first passivation layer within the non-active region and in direct electrical contact with the drain metal 1 fingers, and
a gate metal 1 conductor disposed on the first passivation layer within the non-active region and in direct electrical contact with the gate metal through the gate via;
fabricating a second passivation layer on the first passivation layer and the metal 1 layer using FEOL processes, the second passivation layer comprising:
a source via 2 disposed within the non-active region and over the source metal 1 conductor,
a drain via 2 disposed within the non-active region and over the drain metal 1 conductor, and
a gate a via 2 disposed within the non-active region and over the gate metal 1 conductor.

19. The method of claim 18, further comprising:
fabricating a metal 2 layer on the via 2 layer using FEOL processes, the metal 2 layer comprising:
a source metal 2 conductor disposed on the second passivation layer and in electrical communication with the source metal 1 conductor through the source via 2,
a drain metal 2 conductor disposed on the second passivation layer and in electrical communication with the drain metal 1 conductor through the drain via 2, and.
a gate metal 2 conductor disposed on the second passivation layer and in electrical communication with the gate metal 1 conductor through the gate via 2;
fabricating a third passivation layer on the second via layer and the metal 2 layer using back end of line (BEOL) processes, the third passivation layer comprising:
a source passivation via 3 disposed over the source metal 2 conductor,
a drain passivation via 3 disposed over the drain metal 2 conductor, and
a gate passivation via 3 disposed over gate metal conductor; and
fabricating a metal 3 layer on the third passivation layer using BEOL processes, the metal 3 layer comprising:
a source metal 3 conductor disposed on the third passivation layer and in electrical communication with the source metal 2 conductor through the source via 3,
a drain metal 3 conductor disposed on the third passivation layer and in electrical communication with the drain metal 2 conductor through the drain via 3 and
a gate metal 3 conductor disposed on the third passivation layer and in electrical communication with the gate metal 2 conductor through the gate via 3;
fabricating a forth passivation layer on the third via layer and the metal 3 layer using BEOL processes, the forth passivation layer comprising:
a source passivation via 4 disposed over the source metal 3 conductor, and
a drain passivation via 4 disposed over the drain metal 3 conductor;
a metal 4 layer disposed on the forth passivation layer, the metal 4 layer comprising:
a source metal 4 conductor disposed on the third passivation layer and in electrical communication with the source metal 3 conductor through the source via 4, and
a drain metal 4 conductor disposed on the forth passivation layer and in electrical communication with the drain metal 3 conductor through the drain via 4; and
fabricating a fifth passivation layer on the forth via layer and the metal 4 layer using BEOL processes, the fifth passivation layer comprising:
a source passivation via 5 disposed over the source metal 4 conductor, and
a drain passivation via 5 disposed over the drain metal 4 conductor;
a metal 5 layer disposed on the fifth passivation layer, the metal 5 layer comprising:
a source metal 5 conductor disposed on the forth passivation layer and in electrical communication with the source metal 4 conductor through the source via 5, and
a drain metal 5 conductor disposed on the fifth passivation layer and in electrical communication with the drain metal 4 conductor through the drain via 5.

20. The method of claim 18, further comprising:
fabricating a metal 2 layer on the via 2 layer using BEOL processes, the metal 2 layer comprising:
a source metal 2 conductor disposed on the second passivation layer and in electrical communication with the source metal 1 conductor through the source via 2,
a drain metal 2 conductor disposed on the second passivation layer and in electrical communication with the drain metal 1 conductor through the drain via 2, and.
a gate metal 2 conductor disposed on the second passivation layer and in electrical communication with the gate metal 1 conductor through the gate via 2;
fabricating a third passivation layer on the second via layer and the metal 2 layer using back end of line (BEOL) processes, the third passivation layer comprising:
a source passivation via 3 disposed over the source metal 2 conductor,
a drain passivation via 3 disposed over the drain metal 2 conductor, and
a gate passivation via 3 disposed over gate metal conductor; and
fabricating a metal 3 layer on the third passivation layer using BEOL processes, the metal 3 layer comprising:
a source metal 3 conductor disposed on the third passivation layer and in electrical communication with the source metal 2 conductor through the source via 3,
a drain metal 3 conductor disposed on the third passivation layer and in electrical communication with the drain metal 2 conductor through the drain via 3 and
a gate metal 3 conductor disposed on the third passivation layer and in electrical communication with the gate metal 2 conductor through the gate via 3;
fabricating a forth passivation layer on the third via layer and the metal 3 layer using BEOL processes, the forth passivation layer comprising:
a source passivation via 4 disposed over the source metal 3 conductor, and
a drain passivation via 4 disposed over the drain metal 3 conductor;
a metal 4 layer disposed on the forth passivation layer, the metal 4 layer comprising:
a source metal 4 conductor disposed on the third passivation layer and in electrical communication with the source metal 3 conductor through the source via 4, and
a drain metal 4 conductor disposed on the forth passivation layer and in electrical communication with the drain metal 3 conductor through the drain via 4; and
fabricating a fifth passivation layer on the forth via layer and the metal 4 layer using BEOL processes, the fifth passivation layer comprising:
a source passivation via 5 disposed over the source metal 4 conductor, and
a drain passivation via 5 disposed over the drain metal 4 conductor;
a metal 5 layer disposed on the fifth passivation layer, the metal 5 layer comprising:
a source metal 5 conductor disposed on the forth passivation layer and in electrical communication with the source metal 4 conductor through the source via 5, and
a drain metal 5 conductor disposed on the fifth passivation layer and in electrical communication with the drain metal 4 conductor through the drain via 5.

21. The method of claim 18, wherein the fabricated device is a GaAs device.
